(19) United States
(12) Patent Application Publication
(10) Pub. No.: US 2025/0079249 A1
(43) Pub. Date: Mar. 6, 2025

(54) SEMICONDUCTOR PACKAGE AND METHOD OF MANUFACTURING THE SEMICONDUCTOR PACKAGE

(71) Applicant: Samsung Electronics Co., Ltd., Suwon-si (KR)

(72) Inventors: Yeongbeom Ko, Suwon-si (KR); Kyounglim Suk, Suwon-si (KR); Jaegun Shin, Suwon-si (KR); Sanghoon Lee, Suwon-si (KR); Woojin Jang, Suwon-si (KR); Gwangjae Jeon, Suwon-si (KR)

(21) Appl. No.: 18/791,760

(22) Filed: Aug. 1, 2024

(30) Foreign Application Priority Data
Sep. 4, 2023 (KR) 10-2023-0116901

(51) Int. Cl. H01L 23/31; H01L 21/56; H01L 23/00; H01L 23/29; H01L 25/18

(52) U.S. Cl. CPC H01L 23/3135; H01L 23/29; H01L 23/3171; H01L 24/08; H01L 21/563; H01L 21/568; H01L 25/18; H01L 2224/08121; H01L 2224/08145; H01L 2924/1431

(57) ABSTRACT

A semiconductor package includes a buffer die, an intermediate core die stack on the buffer die, where the intermediate core die stack includes a plurality of intermediate core dies and a plurality of first gap filling portions that respectively overlap side surfaces of the plurality of intermediate core dies in a first direction, a top core die on the intermediate core die stack, and a second gap filling portion that overlaps side surfaces of the intermediate core die stack in the first direction and side surfaces of the top core die in the first direction.

### PRIORITY STATEMENT

This application claims priority under 35 U.S.C. § 119 to Korean Patent Application No. 10-2023-0116901, filed on Sep. 4, 2023 in the Korean Intellectual Property Office (KIPO), the contents of which are herein incorporated by reference in their entirety.

### TECHNICAL FIELD

Example embodiments relate to a semiconductor package and a method of manufacturing the semiconductor package. More particularly, example embodiments relate to a semiconductor package including a plurality of sequentially stacked semiconductor chips and a method of manufacturing the same.

### BACKGROUND

To manufacture a multi-chip package in which at least four semiconductor chips are stacked, a gap filling layer is formed to cover or overlap intermediate core dies on a carrier substrate to form a reconstructed wafer. The reconstructed wafers may be bonded to each other by wafer-to-wafer bonding, and cutting the gap filling layer by a sawing process along a cutting region to form an individual semiconductor package. In this case, the gap filling layer that is exposed through the sawing process may be exposed to the outside and be vulnerable to the external environment. Additionally, since the relatively thick gap filling layer may be cut after stacking the reconstructed wafers, it may not be easy to perform the sawing process. Moreover, when the reconstructed wafers are bonded, bonding defects may occur due to corrosion of the gap filling layer in the cutting region between bonded intermediate core dies at the same level.

### SUMMARY

Example embodiments provide a semiconductor package having improved bonding quality.

Example embodiments provide a method of manufacturing the semiconductor package.

According to example embodiments, a semiconductor package includes a buffer die, an intermediate core die stack on the buffer die, where the intermediate core die stack includes a plurality of intermediate core dies and a plurality of first gap filling portions that respectively overlap side surfaces of the plurality of intermediate core dies in a first direction, a top core die on the intermediate core die stack, and a second gap filling portion that overlaps side surfaces of the intermediate core die stack in the first direction and side surfaces of the top core die in the first direction.

According to example embodiments, a semiconductor package includes a buffer die, a plurality of reconstruction dies that are on the buffer die, where each of the plurality of reconstruction dies includes an intermediate core die and a first gap filling portion that overlaps a side surface of the intermediate core die in a first direction, a top core die on the plurality of reconstruction dies, and a second gap filling portion that overlaps side surfaces of the plurality of reconstruction dies in the first direction and side surfaces of the top core die in the first direction, where each of the plurality of reconstruction dies includes: a substrate, a front insulating layer on a front surface of the substrate, a first bonding pad in the front insulating layer, a backside insulating layer on a backside surface of the substrate, and a second bonding pad in the backside insulating layer, and where the second gap filling portion directly contacts the first gap filling portion of each of the plurality of reconstruction dies.

According to example embodiments, a semiconductor package includes a buffer die, an intermediate core die stack on the buffer die, a top core die on the intermediate core die stack, and a molding member that at least partially overlaps side surfaces of the intermediate core die stack and the top core die, where the intermediate core die stack includes: a plurality of intermediate core dies that are stacked on one another, and a plurality of gap fill portions that at least partially overlap respective side surfaces of the plurality of intermediate core dies, and where the molding member directly contacts the plurality of gap fill portions.

According to example embodiments, a semiconductor package may include an intermediate core die stack having first, second and third reconstruction dies sequentially stacked on a buffer die, a top core die on the intermediate core die stack, and a second gap filling portion covering or overlapping side surfaces of the intermediate core die stack and the top core die. Each of the first, second and third reconstruction dies may include an intermediate core die and a first gap filling portion covering or overlapping a side surface of the intermediate core die.

The first, second and third reconstruction dies may be bonded to each other by wafer-to-wafer bonding at a wafer level. The first, second and third reconstruction dies may be formed by cutting first gap filling portion of reconstruction wafers formed on a carrier substrate along a cutting region through a first sawing process.

Accordingly, voids may be prevented from occurring at bonding interfaces between the intermediate core dies of the first, second and third reconstruction dies to thereby improve the bonding quality.

In addition, the second gap fill filling portion may be formed in a portion created by removing a portion of a first gap filling layer, and then, the second gap filling portion may be cut along the cutting region through a second sawing process to form individually separated semiconductor packages.

Thus, the first gap filling portion exposed by the first sawing process may be covered or overlapped by the second gap filling portion to thereby prevent the first gap filling from being exposed to the outside. Further, the difficulty of cutting a thick gap filling layer after stacking the reconstruction wafers may be avoided and bonding defects due to corrosion of the gap filling layer in the cutting region between the intermediate core dies at the same level may be prevented.

### BRIEF DESCRIPTION OF THE DRAWINGS

Example embodiments will be more clearly understood from the following detailed description taken in conjunction with the accompanying drawings. FIGS. 1 to 31 represent non-limiting, example embodiments as described herein.

FIG. 1 is a cross-sectional view illustrating a semiconductor package in accordance with example embodiments.

FIG. 2 is an enlarged cross-sectional view illustrating portion ‘A’ in FIG. 1.

FIG. 3 is an enlarged cross-sectional view illustrating portion ‘B’ in FIG. 1.

FIGS. 4, 5, 6, 7, 8, 9, 10, 11, 12, 13, 14, 15, 16, 17, 18, 19, 20, 21, and 22 are views illustrating a method of manufacturing a semiconductor package in accordance with example embodiments.

FIG. 23 is a cross-sectional view illustrating a semiconductor package in accordance with example embodiments.

FIG. 24 is an enlarged cross-sectional view illustrating portion ‘I’ in FIG. 22.

FIGS. 25, 26, 27, 28, 29, 30, and 31 are views illustrating a method of manufacturing a semiconductor package in accordance with example embodiments.

### DETAILED DESCRIPTION

To clarify the present disclosure, parts that are not connected with the description will be omitted, and the same elements or equivalents are referred to by the same reference numerals throughout the specification. Further, since sizes and thicknesses of constituent members shown in the accompanying drawings are arbitrarily given for better understanding and ease of description, the present disclosure is not limited to the illustrated sizes and thicknesses. In the drawings, the thickness of layers, films, panels, regions, etc., are exaggerated for clarity. In the drawings, for better understanding and ease of description, thicknesses of some layers and areas are excessively displayed.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, spatially relative terms, such as “beneath,” “below,” “lower,” “above,” “upper,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations), and the spatially relative descriptors used herein may be interpreted accordingly.

In addition, unless explicitly described to the contrary, the word “comprises”, and variations such as “comprises” or “comprising”, will be understood to imply the inclusion of stated elements but not the exclusion of any other elements. As used herein, the phrase “at least one of A, B, and C” refers to a logical (A OR B OR C) using a non-exclusive logical OR, and should not be construed to mean “at least one of A, at least one of B and at least one of C.” As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, steps, operations, elements and/or components, but do not preclude the presence or addition of one or more other features, steps, operations, elements, components and/or groups thereof. The term “and/or” includes any and all combinations of one or more of the associated listed items. The term “connected” may be used herein to refer to a physical and/or electrical connection and may refer to a direct or indirect physical and/or electrical connection. Components or layers described with reference to “overlap” in a particular direction may be at least partially obstructed by one another when viewed along a line extending in the particular direction or in a plane perpendicular to the particular direction.

Hereinafter, example embodiments will be explained in detail with reference to the accompanying drawings.

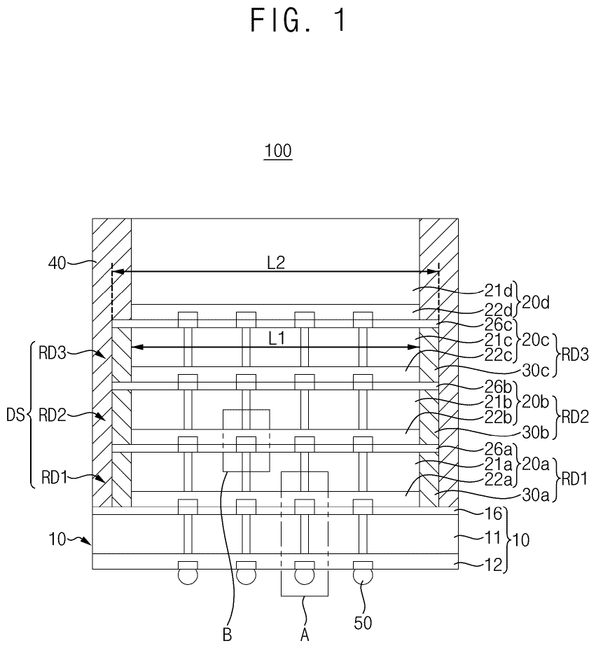

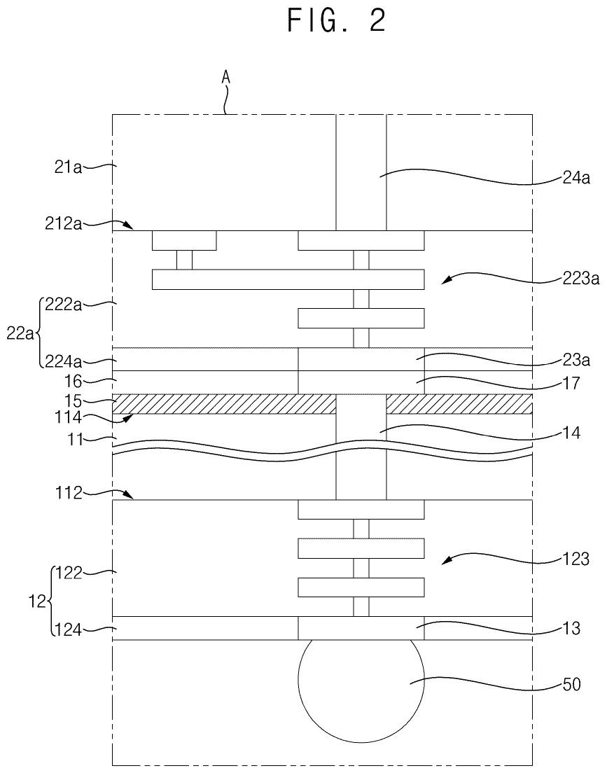

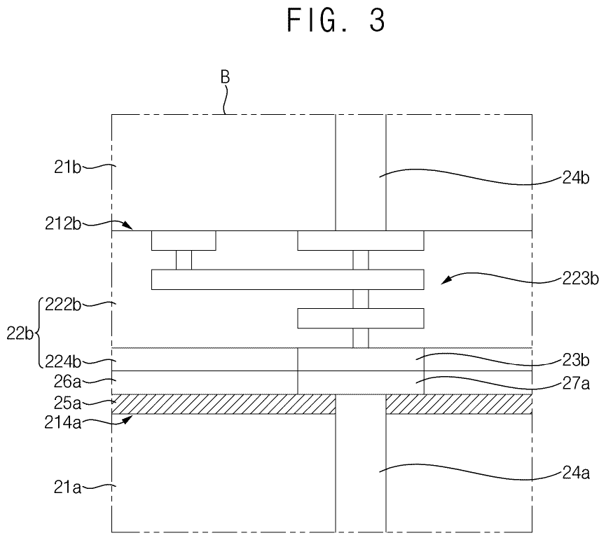

FIG. 1 is a cross-sectional view illustrating a semiconductor package in accordance with example embodiments. FIG. 2 is an enlarged cross-sectional view illustrating portion ‘A’ in FIG. 1. FIG. 3 is an enlarged cross-sectional view illustrating portion ‘B’ in FIG. 1.

Referring to FIGS. 1 to 3, a semiconductor package 100 may include semiconductor chips (also referred to as “dies”) 20 stacked therein. The semiconductor package 100 may include a buffer die 10, an intermediate core die stack DS and a top core die 20d sequentially stacked on the buffer die 10. The intermediate core die stack DS may include first, second and third reconstruction dies RD1, RD2 and RD3 that are sequentially stacked. Each of the first, second and third reconstruction dies RD1, RD2 and RD3 may include an intermediate core die 20a, 20b, 20c, respectively, and a first gap filling portion 30a, 30b, 30c, respectively, covering or overlapping a side surface of the intermediate core die. Additionally, the semiconductor package 100 may further include a second gap filling portion 40 as a molding member that covers or overlaps side surfaces of the intermediate core die stack DS and the top core die 20d.

A plurality of semiconductor chips (dies) 20a, 20b, 20c and 20d may be stacked vertically. In this embodiment, the semiconductor chips (dies) 20a, 20b, 20d and 20d may be substantially the same as or similar to each other. Accordingly, same or like reference numerals will be used to refer to the same or like elements and repeated descriptions of the same elements may be omitted.

In some embodiments, the semiconductor package as a multi-chip package is illustrated as including four stacked semiconductor chips 20a, 20b, 20c and 20d on the buffer die 10, however, it may not be limited thereto. For example, the semiconductor package may include 8, 12, or 16 stacked semiconductor chips.

Each of the semiconductor chips 20a, 20b, 20c and 20d may include an integrated circuit chip completed by performing semiconductor manufacturing processes. Each semiconductor chip may include, for example, a memory chip or a logic chip. The semiconductor package 100 may include a memory device. The memory device may include a high bandwidth memory (HBM) device.

In example embodiments, a buffer die 10 may include a substrate 11, a front insulating layer 12, a plurality of first bonding pads 13, a plurality of through electrodes 14, a backside insulating layer 16, and a plurality of second bonding pads 17. Additionally, the buffer die 10 may further include conductive bumps 50 as conductive connection members respectively provided on the first bonding pads 13. The buffer die 10 may be mounted on a package substrate or an interposer via the conductive bumps 50. For example, the conductive bump 50 may include a solder bump. In some embodiments, the conductive bump 50 may include a pillar bump and a solder bump formed on the pillar bump.

The substrate 11 may have a first surface 112 and a second surface 114 opposite to the first surface 112. The first surface 112 may be an active surface, and the second surface 114 may be a non-active surface. Circuit patterns may be provided on the first surface 112 of the substrate 11. The first surface 112 may be referred to as a front surface on which the circuit patterns are formed, and the second surface may be referred to as a backside surface.

For example, the substrate 11 may be a single crystal silicon substrate. The circuit patterns may include transistors, capacitors, diodes, etc. The circuit patterns may constitute circuit elements. Accordingly, the buffer die 10 may be a semiconductor device having a plurality of circuit elements formed therein.

As illustrated in FIG. 2, the front insulating layer 12 may be formed on the first surface 112 of the substrate 11, that is, the front surface. The front insulating layer 12 may include a plurality of insulating layers 122 and 124 and wirings 123 in the insulating layers. Additionally, the first bonding pad 13 may be provided in an outermost insulating layer of the front insulating layer 12.

For example, the front insulating layer 12 may include a metal wiring layer 122 and a first passivation layer 124. The metal wiring layer 122 may include a plurality of wirings 123 therein. For example, the metal wiring layer 122 may include a metal wiring structure including a plurality of wirings 123 vertically stacked in buffer layers and insulating layers. The first bonding pad 13 may be formed on an uppermost wiring among the plurality of wirings 123. For example, the wirings may include aluminum (Al), copper (Cu), tin (Sn), nickel (Ni), gold (Au), platinum (Pt), or alloys thereof.

The first passivation layer 124 may be formed on the metal wiring layer 122 and may expose at least a portion of the first bonding pad 13. The first passivation layer 124 may include a plurality of stacked insulating layers. For example, the first passivation layer 224 may include a first protective layer including an oxide layer and a second protective layer including a nitride layer, and the first and second protective layers may be sequentially stacked. The first protective layer may include silicon oxide, and the second protective layer may include silicon nitride or silicon carbonitride.

The first bonding pad 13 may be provided in the first passivation layer 124. The first bonding pad 13 may be exposed through a side surface of the first passivation layer 124.

Although not illustrated in the figures, an insulation interlayer may be provided on the first surface 112 of the substrate 11 to cover or overlap the circuit patterns. The insulation interlayer may be formed to include, for example, silicon oxide or a low dielectric material. The insulation interlayer may include lower wiring therein, which are electrically connected to the circuit patterns. Accordingly, the circuit pattern may be electrically connected to the first bonding pad 13 by the lower wirings and the wirings.

The through electrode (e.g., a through silicon via, (TSV)) 14 may vertically penetrate the insulation interlayer and extend from the first surface 112 to the second surface 114 of the substrate 11. The through electrode 14 may contact a lowermost wiring of the metal wiring structure. Accordingly, the through electrode 24 may be electrically connected to the first bonding pad 13 by the wirings 123.

The backside insulating layer 16 may be formed on the second surface 114 of the substrate 11, that is, the backside surface. The second bonding pad 17 may be provided in the backside insulating layer 16. For example, the second bonding pad 17 may be disposed on an exposed surface of the through electrode 14. The backside insulating layer 16 may include silicon oxide, carbon-doped silicon oxide, silicon carbonitride (SiCN), etc. Accordingly, the first and second bonding pads 13 and 17 may be electrically connected to each other by the through electrode 24.

In example embodiments, the intermediate core die stack DS may include first, second and third core dies 20a, 20b and 20c that collectively form a plurality of intermediate cores and first gap filling portions 30a, 30b and 30c that cover or overlap side surfaces of the first, second and third core dies 20a, 20b, and 20c respectively. Each of the first, second and third core dies 20a, 20b and 20c may include a substrate 21a, 21b, 21c, respectively. Each of the first, second and third core dies 20a, 20b and 20c may include a front insulating layer 22a, 22b, 22c provided on a front surface of the substrate 21a, 21b, 21c, respectively. Each of the first, second and third core dies 20a, 20b and 20c may include a first bonding pad 23a, 23b, 23c, respectively, and a backside insulating layer 26a, 26b, 26c provided on a backside surface of the substrate 21a, 21b, 21c, respectively. Each of the first, second and third core dies 20a, 20b and 20c may include a second bonding pad 27a, 27b, 27c, respectively. In addition, each of the first, second and third core dies 20a, 20b and 20c may further include a through electrode 24a, 24b, 24c, respectively that penetrates or extends into the substrate 21a, 21b, 21c, respectively and is electrically connected to the first and second bonding pads 23a, 23b, 23c and 27a, 27b, 27c.

In particular, the intermediate core die stack DS may be bonded onto the buffer die 10. The intermediate core die stack DS may include the first, second and third reconstruction dies RD1, RD2 and RD3 stacked in three stages. The first reconstruction die RD1 may include the first core die 20a and the first gap filling portion 30a covering or overlapping the side surface of the first core die 20a. The second reconstruction die RD2 may include the second core die 20b and the first gap filling portion 30b covering or overlapping the side surface of the second core die 20b. The third reconstruction die RD3 may include the third core die 20c and the first gap filling portion 30c covering or overlapping the side surface of the third core die 20c. In some embodiments, the intermediate core die stack DS may include, but is not limited to, the reconstruction dies RD1, RD2 and RD3 stacked in three stages. For example, the intermediate core die stack DS may include intermediate core dies stacked in 7, 11, 15 stages, etc.

As illustrated in FIGS. 2 and 3, the first core die 20a of the first-stage first reconstruction die RD1 may include a substrate 21a, a front insulating layer 22a, a plurality of first bonding pads 23a, a plurality of through electrodes 24a, a backside insulating layer 26a and a plurality of second bonding pads 27a.

The substrate 21a may have a first surface 212a and a second surface 214a opposite to the first surface 212a. The first surface 212a may be an active surface, and the second surface 214a may be a non-active side. Circuit patterns may be provided on the first surface 212a of the substrate 21a. The front insulating layer 22a may be formed on the first surface 212a of the substrate 21a, that is, a front surface. The front insulating layer 22a may include a plurality of insulating layers 222a and 224a and wirings 223a in the insulating layers 222a and 224a. Additionally, the first bonding pad 23a may be provided in an outermost insulating layer of the front insulating layer 22a. For example, the front insulating layer 22a may include a metal wiring layer 222a and a first passivation layer 224a. The metal wiring layer 222a may include a plurality of wirings 223a therein.

The through electrode 24a may vertically extend from the first surface 212a to the second surface 214a of the substrate 21a. The through electrode 24a may be electrically connected to the first bonding pad 23a by the wirings 223a. The backside insulating layer 26a may be formed on the second surface 214a of the substrate 21a, that is, a backside surface. The second bonding pad 27a may be provided in the backside insulating layer 26a. Accordingly, the first and second bonding pads 23a and 27a may be electrically connected to each other by the through electrode 24a.

The backside insulating layer 26a may protrude or extend in a horizontal direction from the side surfaces of the substrate 21a and the front insulating layer 22a. The substrate 21a and the front insulating layer 22a may have a length in a first direction, that is, a first width L1, and the backside insulating layer 26a may have a second width L2 greater than the first width L1.

Similarly, the second core die 20b of the second-stage second reconstruction die RD2 may include a substrate 21b, a front insulating layer 22b, a plurality of first bonding pads 23b, a plurality of through electrodes 24b, a backside insulating layer 26b, and a plurality of second bonding pads 27b. Since the core dies 20a, 20b, 20c and 20d are substantially the same as or similar to each other, same or like reference numerals will be used to refer to the same or like elements and repeated descriptions of the same elements may be omitted.

As illustrated in FIG. 2, the first core die 20a and the buffer die 10 may be bonded to each other by hybrid bonding. The second bonding pad 17 of the buffer die 10 and the first bonding pad 23a of the first core die 20a may be bonded to each other by copper-copper hybrid bonding (Cu—Cu Hybrid Bonding). The front surface of the first core die 20a, that is, the front side insulating layer 22a on the first surface 212a of the substrate 21a may be directly bonded to the backside insulating layer 16 of the substrate 11 of the buffer die 10.

As illustrated in FIG. 3, the second core die 20b and the first core die 20a may be bonded to each other by hybrid bonding. The second bonding pad 27a of the first core die 20a and the first bonding pad 23b of the second core die 20b may be bonded to each other by copper-copper hybrid bonding (Cu—Cu Hybrid Bonding).

The front insulating layer 22b on the front surface of the second core die 20b may be directly bonded to the backside insulating layer 26a on the backside surface of the first core die 20a. The outermost insulating layers of the backside insulating layer 26a and the front insulating layer 22b may include an insulating material that contacts each other and provides relatively greater bonding strength, thereby providing a bonding structure. The backside insulating layer 26a and the front insulating layer 22b may be bonded to each other by a high temperature annealing process while in contact with each other. Here, the bonding structure may have a relatively stronger bonding strength by covalent bonding.

Similarly, the third core die 20c and the second core die 20b may be bonded to each other by hybrid bonding. The second bonding pad 27b of the second core die 20b and a first bonding pad 23c of the third core die 20c may be bonded to each other by copper-copper hybrid bonding (Cu—Cu Hybrid Bonding). A front insulating layer 22c on the front surface of the third core die 20c may be directly bonded to the backside insulating layer 26b on the backside surface of the second core die 20b.

The first gap filling portion 30a of the first reconstruction die RD1 may at least partially cover or overlap the side surface of the first core dies 20a. The first gap filling portion 30a may cover or overlap the side surfaces of the substrate 21a and the front insulating layer 22a of the first core die 20a. The backside insulating layer 26a of the first core die 20a may cover or overlap an upper surface of the first gap filling portion 30a. The backside insulating layer 26a may protrude or extend in a horizontal direction from the side surfaces of the substrate 21a and the front insulating layer 22a, and the protruding portion of the backside insulating layer 26a may cover or overlap the upper surface of the first gap filling portion 30a. The side surface of the backside insulating layer 26a and the side surface of the first gap filling portion 30a may be positioned on the same plane.

For example, the first gap filling portion 30a may be formed by a conformal deposition process, such as an atomic layer deposition (ALD) process or a chemical vapor deposition (CVD) process. The first gap filling portion may include an inorganic dielectric layer or an organic dielectric layer. The inorganic dielectric layer may include silicon oxide, silicon oxynitride, phosphosilicate glass (PSG), boro-phosphosilicate glass (BPSG), etc. The organic dielectric layer may include a polymer or the like.

In some embodiments, the first gap filling portion 30a of the first reconstruction die RD1 may cover or overlap the entire side surface of the first core die 20a. The first gap filling portion 30a of the first reconstruction die RD1 may cover or overlap the side surfaces of the substrate 21a, the front insulating layer 22a, and the backside insulating layer 26a of the first core die 20a. In this case, the backside insulating layer 26a may not protrude or extend in the horizontal direction from the side surfaces of the substrate 21a and the front insulating layer 22a, and the side surfaces of the backside insulating layer 26a and the substrate 21a and the front insulating layer 22a may be positioned on the same plane.

Similarly, the first gap filling portion 30b of the second reconstruction die RD2 may at least partially cover or overlap the side surface of the second core dies 20b. The first gap filling portion 30b may cover or overlap the side surfaces of the substrate 21b and the front insulating layer 22b of the second core die 20b. The backside insulating layer 26b of the second core die 20b may cover or overlap an upper surface of the first gap filling portion 30b. The backside insulating layer 26b may protrude or extend in a horizontal direction from the side surfaces of the substrate 21b and the front insulating layer 22b, and the protruding portion of the backside insulating layer 26b may cover or overlap the upper surface of the first gap filling portion 30b. The side surface of the backside insulating layer 26b and the side surface of the first gap filling portion 30b may be positioned on the same plane.

In some embodiments, the first gap filling portion 30b of the second reconstruction die RD2 may cover or overlap the entire side surface of the second core die 20b. The first gap filling portion 30b of the second reconstruction die RD2 may cover or overlap the side surfaces of the substrate 21b, the front insulating layer 22b, and the backside insulating layer 26b of the second core die 20b. In this case, the backside insulating layer 26b may not protrude or extend in the horizontal direction from the side surfaces of the substrate 21b and the front insulating layer 22b, and the side surfaces of the backside insulating layer 26b and the substrate 21b and the front insulating layer 22b may be positioned on the same plane.

Similarly, the first gap filling portion 30c of the third reconstruction die RD3 may at least partially cover or overlap the side surface of the third core dies 20c. The first gap filling portion 30c may cover or overlap the side surfaces of the substrate 21c and the front insulating layer 22c of the third core die 20c. The backside insulating layer 26c of the third core die 20c may cover or overlap an upper surface of the first gap filling portion 30c. The backside insulating layer 26c may protrude or extend in a horizontal direction from the side surfaces of the substrate 21c and the front insulating layer 22c, and the protruding portion of the backside insulating layer 26c may cover or overlap the upper surface of the first gap filling portion 30c. The side surface of the backside insulating layer 26c and the side surface of the first gap filling portion 30c may be positioned on the same plane.

In some embodiments, the first gap filling portion 30c of the third reconstruction die RD3 may cover or overlap the entire side surface of the third core die 20c. The first gap filling portion 30c of the third reconstruction die RD3 may cover or overlap the side surfaces of the substrate 21c, the front insulating layer 22c, and the backside insulating layer 26c of the third core die 20c. In this case, the backside insulating layer 26c may not protrude or extend in the horizontal direction from the side surfaces of the substrate 21c and the front insulating layer 22c, and the side surfaces of the backside insulating layer 26c and the substrate 21c and the front insulating layer 22c may be positioned on the same plane.

As illustrated in FIG. 1, the backside insulating layer 26a of the first reconstruction die RD1 may cover or overlap a lower surface of the first gap filling portion 30b of the second reconstruction die RD2. The backside insulating layer 26b of the second reconstruction die RD2 may cover or overlap a lower surface of the first gap filling portion 30c of the third reconstruction die RD3.

In example embodiments, the top core die 20d may be bonded onto the intermediate core die stack DS. A thickness of the top core die 20d may be greater than a thickness of each of the intermediate core dies 20a, 20b, 20c. The thickness of the top core die 20d may be in a range of 100 μm to 300 μm. The thickness of each of the intermediate core dies 20a, 20b, 20c may be in a range of 20 μm to 50 μm.

The top core die 20d and the third core die 20c of the intermediate core die stack DS may be bonded to each other by hybrid bonding. A front insulating layer 22d on a front surface of the top core die 20d may be directly bonded to a backside insulating layer 26c on a backside surface of the third core die 20c, and a second bonding pad 27c of the third die 20c and a first bonding pads 23d of the top core die 20d may be bonded to each other by copper-copper hybrid bonding.

In example embodiments, the second gap filling portion 40 (as a molding member) may be provided to cover or overlap side surfaces of the intermediate core die stack DS and the top core die 20d. The second gap filling portion 40 may cover or overlap side surfaces of the first to third reconstruction dies RD1, RD2 and RD3 and the top core die 20d. The second gap filling portion 40 may directly contact the first gap fill portions 30a, 30b and 30c of the first to third reconstruction dies RD1, RD2, and RD3. The second gap filling portion 40 may cover or overlap a portion of the backside insulating layer 26c of the third reconstruction die RD3 exposed by the top core die 20d.

For example, the second gap filling portion 40 may include a molding material, such as a thermosetting resin. The molding material may include an epoxy mold compound (EMC). The molding material may include UV resin, polyurethane resin, silicone resin, silica filler, etc.

In example embodiments, a width of buffer die 10 may be the same as a width of intermediate core die stack DS. The width of the intermediate core die stack DS may be greater than a width of the top core die 20d.

As mentioned above, the semiconductor package 100 may include the intermediate core die stack DS having the first, second and third reconstruction dies RD1, RD2 and RD3 sequentially stacked on the buffer die 10, the top core die 20d, and the second gap filling portion 40 covering or overlapping the side surfaces of the intermediate core die stack DS and the top core die 20d. Each of the first, second and third reconstruction dies RD1, RD2 and RD3 may include the intermediate core die 20a, 20b, 20c, respectively, and the first gap filling portion 30a, 30b, 30c, respectively, covering or overlapping the side surface of the intermediate core die 20a, 20b, 20c, respectively.

The first, second and third reconstruction dies RD1, RD2 and RD3 of the intermediate core die stack DS may be bonded to each other by wafer-to-wafer bonding at a wafer level. The first, second and third reconstruction dies RD1, RD2 and RD3 may be formed respectively by cutting first gap filling layers of reconstruction wafers formed on a carrier substrate along a cutting region through a first sawing process.

Accordingly, voids may be prevented from occurring at bonding interfaces between the first, second and third cores dies 20a, 20b and 20c of the first, second and third reconstruction dies RD1, RD2 and RD3, respectively, thereby improving the bonding quality.

In addition, the second gap fill filling portion may be formed in a portion created by removing a portion of the first gap filling layer, and then, the second gap filling portion may be cut along the cutting region through a second sawing process, to form individually separated semiconductor packages.

Thus, the first gap filling portion exposed by the first sawing process may be covered or overlapped by the second gap filling portion, thereby preventing the first gap filling from being exposed to the outside. In addition, the difficulty of cutting a thick gap filling layer after stacking the reconstruction wafers may be avoided and bonding defects due to corrosion of the gap filling layer in the cutting region between the intermediate core dies at the same level may be prevented.

Hereinafter, a method of manufacturing the semiconductor package of FIG. 1 will be described. A case where the semiconductor package includes a high bandwidth memory (HBM) device will be described. However, it will be understood that a method of manufacturing a semiconductor package in accordance with example embodiments is not limited thereto.

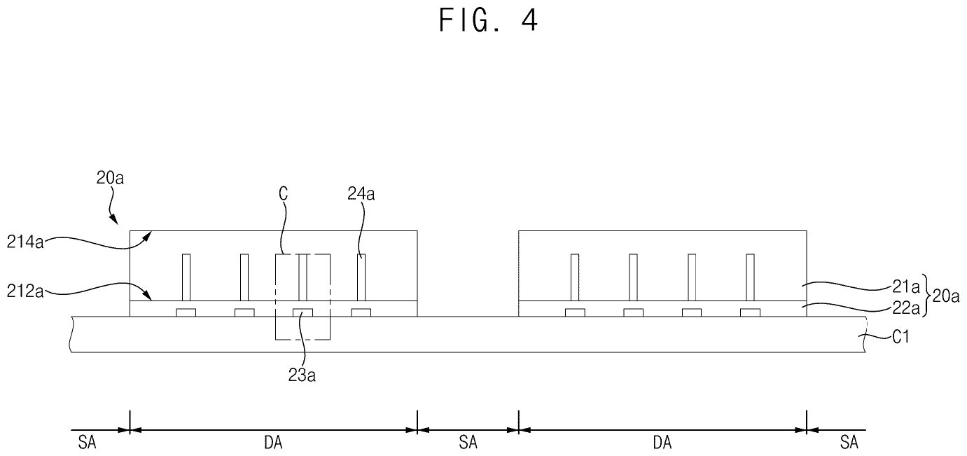

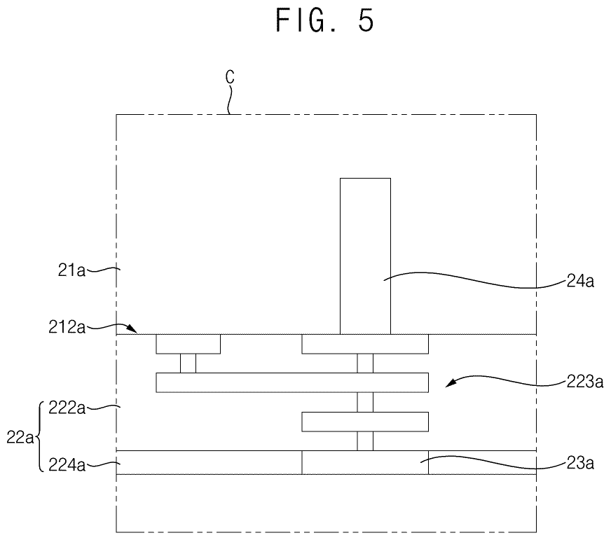

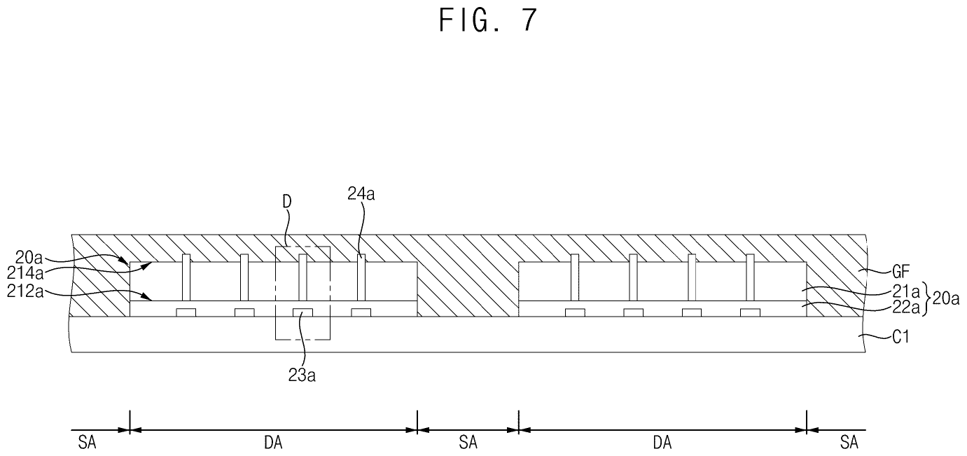

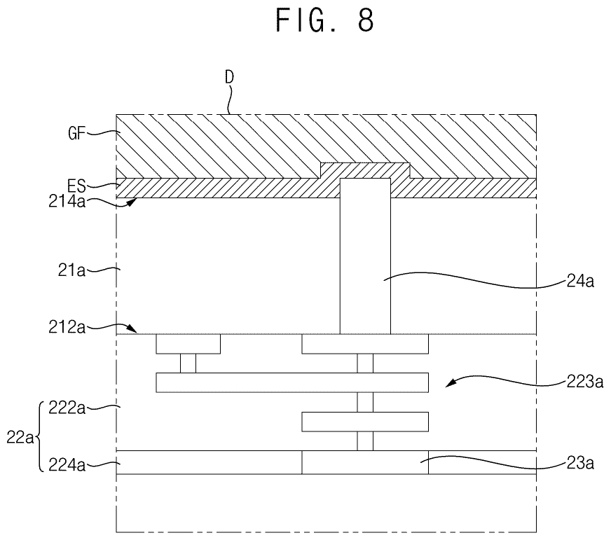

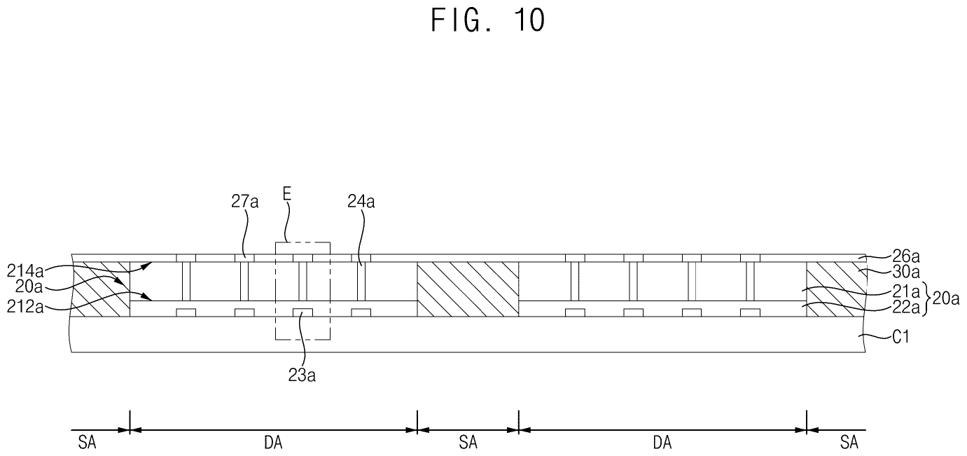

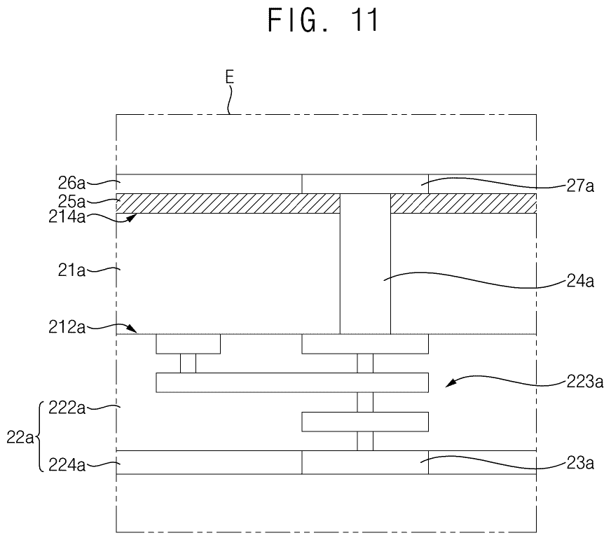

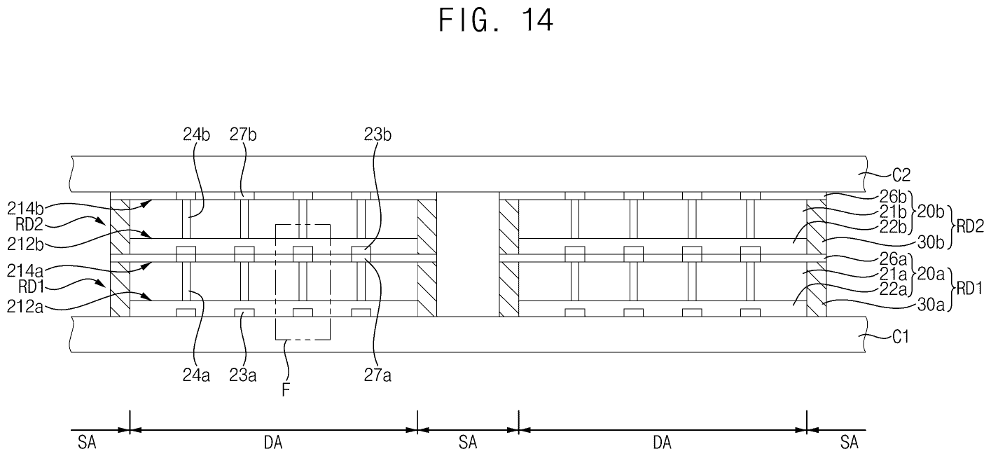

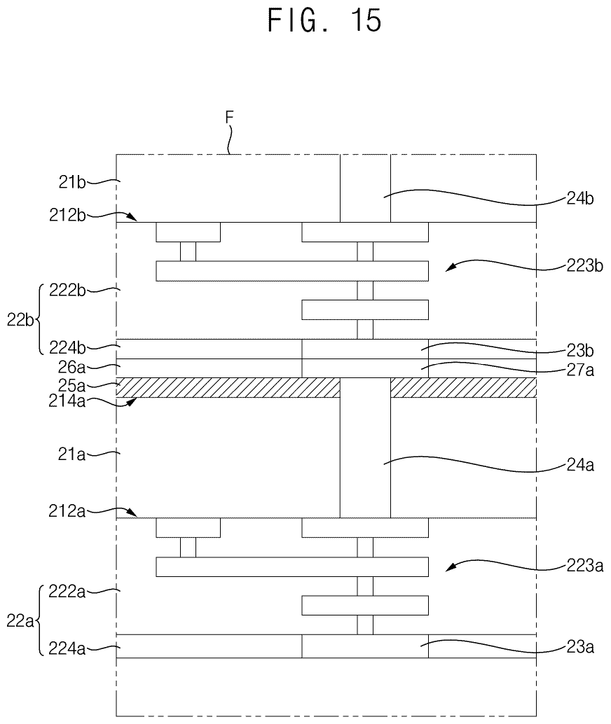

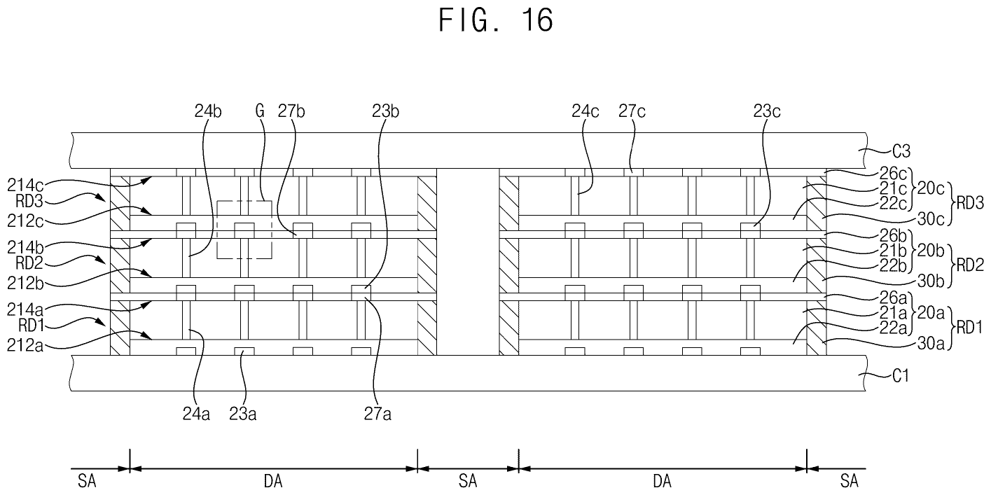

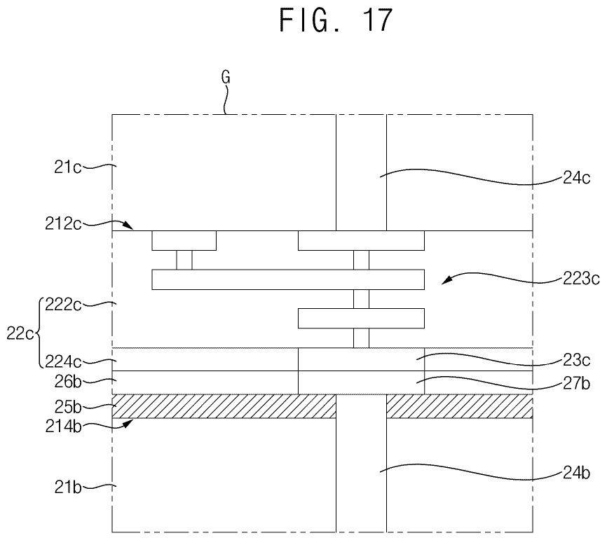

FIGS. 4 to 22 are views illustrating a method of manufacturing a semiconductor package in accordance with example embodiments. FIG. 5 is an enlarged cross-sectional view illustrating portion ‘C’ in FIG. 4. FIG. 8 is an enlarged cross-sectional view illustrating portion ‘D’ in FIG. 7. FIG. 11 is an enlarged cross-sectional view illustrating portion ‘E’ in FIG. 10. FIG. 15 is an enlarged cross-sectional view illustrating portion ‘F’ in FIG. 14. FIG. 17 is an enlarged cross-sectional view illustrating portion ‘G’ in FIG. 16.

Referring to FIGS. 4 to 12, first, a first reconstruction dies RD1 may be formed on a first carrier substrate C1.

As illustrated in FIGS. 4 and 5, a plurality of first semiconductor chips (first core dies) 20a diced from a wafer may be placed on the first carrier substrate C1.

In example embodiments, the first carrier substrate C1 may include a wafer substrate as a base substrate on which the plurality of first core dies are disposed and a first gap filling layer is formed to cover or overlap them to perform wafer-to-wafer bonding at a wafer level. The first carrier substrate C1 may have a shape corresponding to a wafer on which the semiconductor process is performed. For example, the first carrier substrate may include a silicon substrate, a glass substrate, a non-metallic or metallic plate, etc.

The first carrier substrate C1 may include a die region where the first core die is disposed and a cutting region SA at least partially surrounding the die region DA. As will be described later, the first gap filling layer covering or overlapping the first core dies on the first carrier substrate C1 may be cut along the cutting region CR by a first sawing process to be individualized.

As illustrated in FIG. 4, the first core die 20a may include a substrate 21a and a front insulating layer 22a having first bonding pads 23a provided in a side surface thereof. Additionally, the first core die 20a may include a plurality of through electrodes 24a that are provided in the substrate 21a and electrically connected to the first bonding pads 23a.

The substrate 21a may have a first surface 212a and a second surface 214a opposite to each other. For example, the substrate 21a may include silicon, germanium, silicon-germanium, or III-V compounds, e.g., GaP, GaAs, GaSb, etc. In some embodiments, the substrate 21a may be a silicon-on-insulator (SOI) substrate, or a germanium-on-insulator (GOI) substrate.

The circuit patterns may include transistors, capacitors, diodes, etc. The circuit patterns may constitute circuit elements. Accordingly, the semiconductor chip may be a semiconductor device with a plurality of the circuit elements formed therein. The circuit patterns may be formed on the first surface 212a of the substrate 21a by performing a FEOL (Front End of Line) process for manufacturing semiconductor devices. The surface of the substrate on which the FEOL process is performed may be referred to as a front surface of the substrate, and a surface opposite to the front surface may be referred to as a backside surface.

The circuit element may include a plurality of memory devices. Examples of the memory devices include a volatile semiconductor memory device and a non-volatile semiconductor memory device. Examples of the volatile semiconductor memory device may be DRAM, SRAM, etc. Examples of the non-volatile semiconductor memory devices may be EPROM, EEPROM, Flash EEPROM, etc.

As illustrated in FIG. 5, the front insulating layer 22a may be formed as an insulation interlayer on the first surface 212a of the substrate 21a, that is, the front surface. The front insulating layer 22a may include a plurality of insulating layers 222a and 224a and wirings 223a in the insulating layers. Additionally, the first bonding pad 23a may be provided in the outermost insulating layer of the front insulating layer 22a.

For example, the front insulating layer 2a2 may include a metal wiring layer 222a and a first passivation layer 224a. The metal wiring layer 222a may include the plurality of wirings 223a therein. For example, the metal wiring layer 222a may include a metal wiring structure including the plurality of wirings 223a vertically stacked in buffer layers and insulating layers. The first bonding pad 23a may be formed on an uppermost wiring among the plurality of wirings 223. For example, the wirings may include aluminum (Al), copper (Cu), tin (Sn), nickel (Ni), gold (Au), platinum (Pt), or alloys thereof.

The first passivation layer 224a may be formed on the metal wiring layer 222a and may expose at least a portion of the first bonding pad 23a. The first passivation layer 224a may include a plurality of stacked insulating layers. For example, the first passivation layer 224a may include a first protective layer including an oxide layer and a second protective layer including a nitride layer, and the first and second protective layers may be sequentially stacked. The first protective layer may include silicon oxide, and the second protective layer may include silicon nitride or silicon carbonitride.

The first bonding pad 23a may be provided in the first passivation layer 224a. The first bonding pad 23a may be exposed through a side surface of the first passivation layer 224a. Although not illustrated, in some embodiments, an insulation interlayer may be provided on the first surface 212a of the substrate 21a to cover the circuit patterns. The insulation interlayer may be formed to include, for example, silicon oxide or a low dielectric material. The insulation interlayer may include lower wiring therein, which are electrically connected to the circuit patterns. Accordingly, the circuit pattern may be electrically connected to the first bonding pad 23a by the lower wirings and the wirings.

The through electrode (through silicon via, TSV) 24a may vertically penetrate or extend into the insulation interlayer and extend from the first surface 212a of the substrate 21a to a predetermined depth. The through electrode 24a may contact a lowermost wiring of the metal wiring structure. Accordingly, the through electrode 24a may be electrically connected to the first bonding pad 23a by the wirings 223a.

A liner layer (not illustrated) may be provided on a side surface of the through electrode 24a. The liner layer may include silicon oxide or carbon-doped silicon oxide. The liner layer may electrically insulate the through electrode 24a from the substrate 21a and the metal wiring layer 222a.

The through electrode 24a and the first bonding pad 23a may include a same metal. For example, the metal may include copper (Cu). However, it is not limited thereto, and the through electrode and the first bonding pad may include a material (e.g., gold (Au)) that can be bonded by inter-diffusion of metals by a high-temperature annealing process.

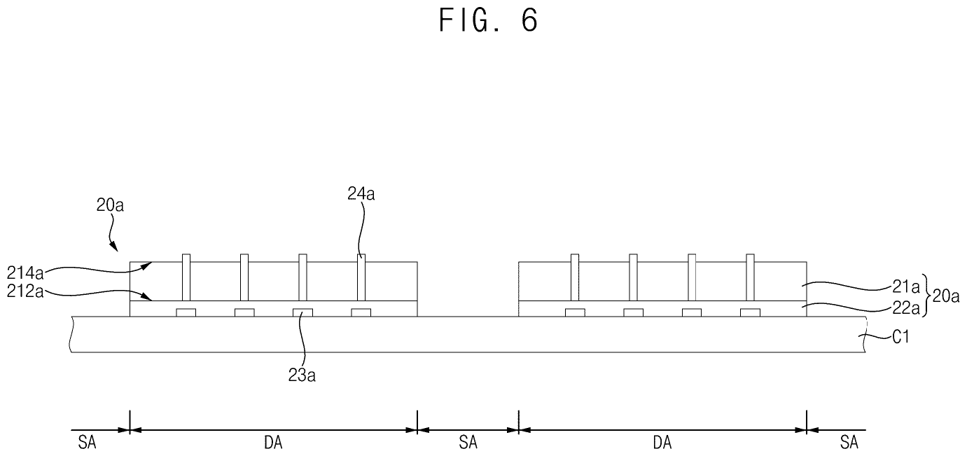

As illustrated in FIG. 6, the second surface 214a of the substrate 21a may be partially removed to expose one end portion of the through electrode 24a.

In example embodiments, first, a grinding process such as a back lap process may be performed to partially remove the second surface 214a of the substrate 21a, and then an etching process, such as a silicon recess process, may be performed to expose the end portion of the through electrode 24a. Accordingly, a thickness of the substrate 21a may be reduced to a desired thickness. For example, the substrate 21a may have the thickness in a range of about m to about 50 μm.

In the back lap process, the entire second surface 214a of the substrate 21a may be grinded. In the silicon recess process, only the silicon in the second surface 214a of the substrate 21a may be selectively etched. The etching process may be an isotropic dry etching process. The etching process may include a plasma etching process, etc. The plasma etching process may be performed using inductively coupled plasma, capacitively coupled plasma, microwave plasma, etc.

Since the grinding process and the etching process are performed in the wafer level, the entire second surface 214 of the substrate 21 may be reduced to a uniform thickness. Accordingly, the end portions of the through electrodes 24 may protrude or extend uniformly from the second surface 214 of the substrate 21 over the entire second surface 214 of the substrate 21 to have same heights from the carrier substrate C1.

As illustrated in FIGS. 7 and 8, a first gap filling layer GF may be formed on the first carrier substrate C1 to cover or overlap the first core dies 20a.

First, an etch stop layer ES may be formed along a profile of the first core dies 20a on the first carrier substrate C1. The etch stop layer ES may be conformally formed to cover or overlap the end portions of the through electrodes 24a that protrude or extend from the second surface 214a of the substrate 21a. The etch stop layer ES may cover or overlap the entire second surface 214a of the substrate 21a. For example, the etch stop layer may have a thickness within a range of 0.1 μm to 1 μm. The etch stop layer may include a material that can be used to detect a polishing end point in a subsequent chemical mechanical polishing process. The etch stop layer may include a silicon nitride layer. The thickness and material of the etch stop layer may be selected in consideration of a polishing selectivity and polishing conditions in the subsequent chemical mechanical polishing process.

Although not illustrated in the figures, in one embodiment, a sacrificial layer may be formed on the etch stop layer ES. The sacrificial layer may be formed to fill or be in a gap between the protruding end portions of the through electrodes 24s. The sacrificial layer may include silicon oxide, such as TEOS.

Then, the first gap filling layer GF may be formed to cover or overlap the etch stop layer ES on the first core dies 20 on the first carrier substrate C1. The first gap filling layer GF may cover or overlap a side surface and an upper surface of the first core dies 20a. For example, the first gap filling layer GF may be formed by a conformal deposition process, such as an atomic layer deposition (ALD) process or a chemical vapor deposition (CVD) process. The first gap filling layer may include an inorganic dielectric layer or an organic dielectric layer. The inorganic dielectric layer may include silicon oxide, silicon oxynitride, phosphosilicate glass (PSG), boro-phosphosilicate glass (BPSG), etc. The organic dielectric layer may include a polymer or the like.

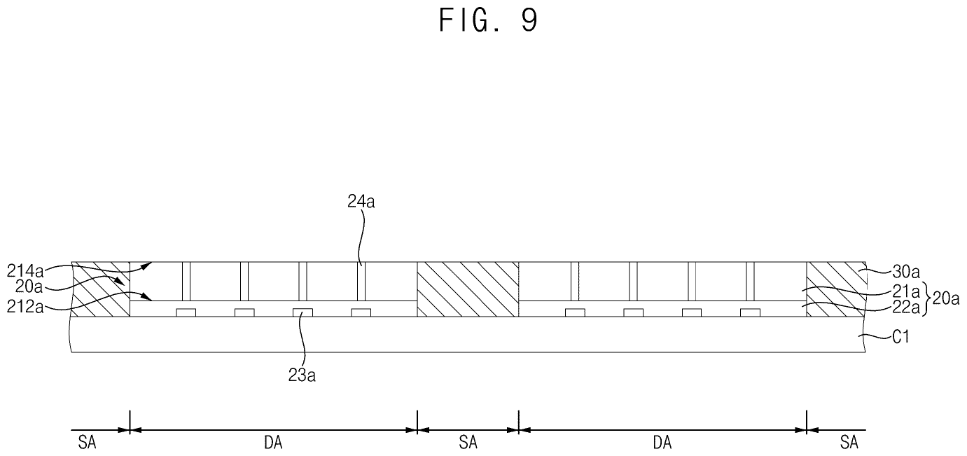

As illustrated in FIG. 9, an upper portion of the first gap filling layer GF may be removed to form a first gap filling portion 30a that covers or overlaps a side surface of the first core die 24a and exposes an upper surface of the first core dire 24a. A chemical mechanical polishing (CMP) process using the etch stop layer to detect a polishing end point may be performed to remove the upper portion of the first gap filling layer GF and the sacrificial layer to expose the end portions of the through electrodes 24a. Through the CMP process, the end portions of the through electrodes 24a and portions of the etch stop layer covering or overlapping them may be removed to form an etch stop layer pattern 25a (see FIG. 11) on the second surface 214a of the substrate 21a.

The first gap fill portion 30a may expose the etch stop layer pattern 25a and end portions of the through electrodes 24a on the second surface 214a of the substrate 21a. The first gap fill portion 30a may cover or overlap the side surfaces of the substrate 21a and the front insulating layer 22a.

As illustrated in FIGS. 10 and 11, a backside insulating layer 26a having a second bonding pad 27a in a side surface thereof may be formed on the second surface 214a of the substrate 21a.

In particular, the backside insulating layer 26a as a second passivation layer having the second bonding pad 27a that is electrically connected to the through electrode 24a may be formed on the etch stop layer pattern 25a on the second surface 214a of the substrate 21a.

The etch stop layer pattern 25a may expose the end portions of the through electrodes 24a. The end portions of the through electrodes 24a may protrude or extend from the second surface 214a of the substrate 21a, and the etch stop layer pattern 25a may cover or overlap sidewalls of the end portions of the through electrodes 24a that protrude or extend from the second surface 214a of the substrate 21a. Accordingly, the upper surfaces of the through electrodes 24a may be exposed by the etch stop layer pattern 25a. An upper surface of the etch stop layer pattern 25a and the exposed upper surfaces of the through electrodes 24a may be positioned on the same plane.

For example, after the backside insulating layer 26a is formed on the etch stop layer pattern 25a on the second surface 214a of the substrate 21a, an opening may be formed in the backside insulating layer 26a to expose the through electrode 24a, and a plating process may be performed to form the second bonding pad 27a in the opening of the backside insulating layer 26a. The second bonding pad 27a may be disposed on the exposed surface of the through electrode 24a. The backside insulating layer 26a may include silicon oxide, carbon-doped silicon oxide, silicon carbonitride (SiCN), etc. Accordingly, the first and second bonding pads 23a and 27a may be electrically connected to each other by the through electrode 24a.

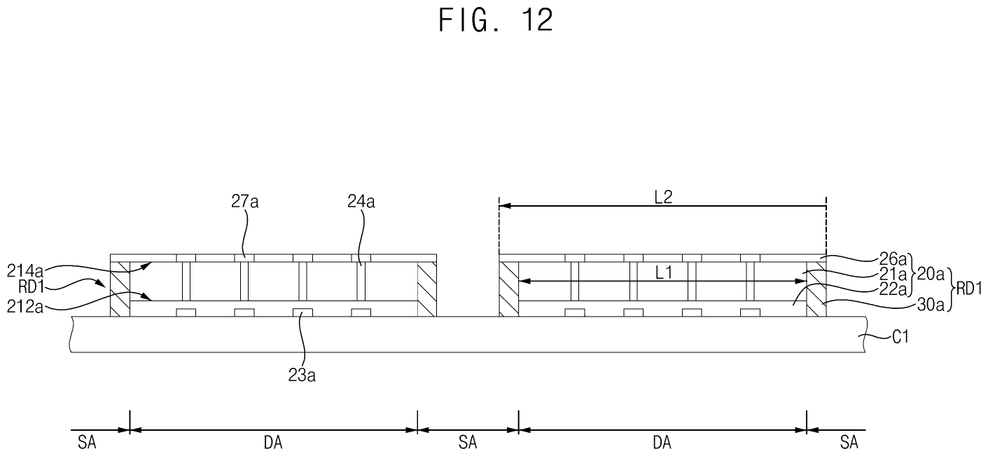

As illustrated FIG. 12, the first gap filling portion 30a may be cut along the cutting region, that is, scribe lane region SA to form individual first reconstruction dies RD1 on the first carrier substrate C1.

The first reconstruction dies RD1 may be spaced apart from each other at the wafer level on the first carrier substrate C1. The first reconstruction dies RD1 may be disposed on the first carrier substrate C1 such that the first surface 212a of the substrate 21a of the first reconstruction die RD1 faces the first carrier substrate C1. Each of the first reconstruction dies RD1 may include the first core die 20a and the first gap filling portion 30a that covers or overlaps the side surface of the first core die 20a. The first gap filling portion 30a may cover or overlap the side surfaces of the substrate 21a and the front insulating layer 22a. The backside insulating layer 26a may cover or overlap the upper surface of the first gap filling portion 30a.

The backside insulating layer 26a may protrude or extend in a horizontal direction from the side surfaces of the substrate 21a and the front insulating layer 22a. The substrate 21a and the front insulating layer 22a may have a length in a first direction, that is, a first width L1, and the backside insulating layer 26a may have a second width L2 greater than the first width L1.

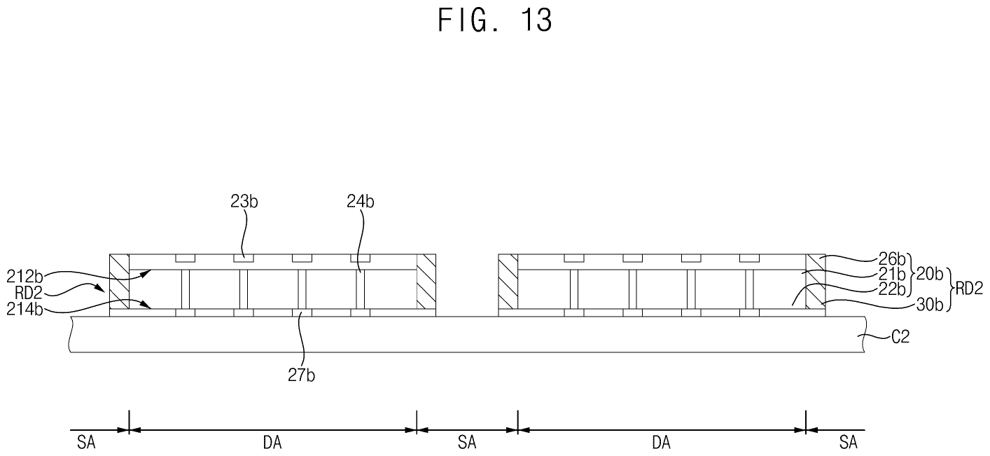

Referring to FIG. 13, processes the same as or similar to the processes described with reference to FIGS. 4 to 12 may be performed to form second reconstruction dies RD2 on a carrier substrate, and the second reconstruction dies RD2 may be attached on a second carrier substrate C2.

Thus, the second reconstruction dies RD2 may be spaced apart from each other at a wafer level on the second carrier substrate C2. The second reconstruction dies RD2 may be disposed on the second carrier substrate C2 such that the second surface 214b of the substrate 21b of the second reconstruction die RD2 faces the second carrier substrate C2. Each of the second reconstruction dies RD2 may include a second core die 20b and a first gap filling portion 30b covering or overlapping a side surface of the second core die 20b. The first gap filling portion 30b may cover or overlap side surfaces of a substrate 21b and a front insulating layer 22b. A backside insulating layer 26b may cover or overlap a lower surface of the first gap filling portion 30b.

Referring to FIGS. 14 and 15, the second reconstruction die RD2 on the second carrier substrate C2 may be attached on the first reconstruction die RD1 on the first carrier substrate C1 (e.g., a wafer-to-wafer hybrid bonding process).

In example embodiments, the second reconstruction die RD2 on the second carrier substrate C2 of FIG. 13 may be bonded to the first reconstruction die RD1 on the first carrier substrate C1 of FIG. 12. A front surface of the second core die 20b of the second reconstruction die RD2 may be stacked to face a backside surface of the first core die 20a of the first reconstruction die RD1.

When the second reconstruction dies RD2 on the second carrier substrate C2 and the first reconstruction dies RD1 on the first carrier substrate C1 are bonded to each other by wafer-to-wafer bonding, the second core die 20b of the second reconstruction die RD2 and the first core die 20a of the first reconstruction die RD1 may be bonded to each other by hybrid bonding by performing a thermal compression process and an annealing process. That is, the front insulating layer 22b on the front surface of the second core die 20b may be directly bonded to the back insulating layer 26a on the backside surface of the first core die 20a, and the second bonding pad 27a of the first core die 20a and the first bonding pad 23b of the second core die 20b may be bonded to each other by copper-Cu hybrid bonding.

The second reconstruction dies RD2 including the second core dies 20b on the second carrier substrate C2 and the first reconstruction dies RD1 including the first core dies 20a on the first carrier substrate C1 may be bonded to each other by wafer-to-wafer bonding. For example, during wafer-to-wafer bonding, after the central portion of the second carrier substrate C2 may be deformed to be convex downward, the second reconstruction die RD2 on the second carrier substrate C2 may be brought into contact with the first reconstruction die RD1 on the first carrier substrate C1. Bonding may begin after the central portion of the second carrier substrate C2 and the central portion of the first carrier substrate C1 firstly contact each other. Accordingly, voids at the bonding interface between the first core die 20a and the second core die 20b may be prevented from occurring, thereby improving the bonding quality.

Referring to FIGS. 16 and 17, processes the same as or similar to the processes described with reference to FIGS. 13 to 15 may be performed to attach third reconstruction dies RD3 in a third stage on the second-stage second reconstruction dies RD2 on the first carrier substrate C1.

First, processes the same as or similar to the processes described with reference to FIGS. 4 to 12 may be performed to form third reconstruction dies RD3 on a carrier substrate, and the third reconstruction dies RD3 may be attached on a third carrier substrate C3.

Thus, the third reconstruction dies RD3 may be spaced apart from each other at a wafer level on the third carrier substrate C3. The third reconstruction dies RD3 may be disposed on the third carrier substrate C3 such that a second surface 214c of a substrate 21c of the third reconstruction die RD3 faces the third carrier substrate C3. Each of the third reconstruction dies RD3 may include a third core die 20c and a first gap filling portion 30c covering or overlapping a side surface of the third core die 20c. The first gap filling portion 30c may cover or overlap side surfaces of a substrate 21c and a front insulating layer 22c. A backside insulating layer 26c may cover or overlap a lower surface of the first gap filling portion 30c.

Then, the third reconstruction die RD3 on the third carrier substrate C3 may be attached on the second reconstruction die RD2 on the first carrier substrate C1 (e.g., a wafer-to-wafer hybrid bonding process).

The third reconstruction die RD3 on the third carrier substrate C3 may be bonded to the second reconstruction die RD2 on the first carrier substrate C1. A front surface of the third core die 20c of the third reconstruction die RD3 may be stacked to face a backside surface of the second core die 20b of the second reconstruction die RD2.

As illustrated in FIG. 17, when the third reconstruction dies RD3 on the third carrier substrate C3 and the second reconstruction dies RD3 on the first carrier substrate C1 are bonded to each other by wafer-to-wafer bonding, the third core die 20c of the third reconstruction die RD3 and the second core die 20b of the second reconstruction die RD2 may be bonded to each other by hybrid bonding by performing a thermal compression process and an annealing process. That is, the front insulating layer 22c on the front surface of the third core die 20c may be directly bonded to the back insulating layer 26b on the backside surface of the second core die 20b, and the second bonding pad 27b of the second core die 20b and the first bonding pad 23c of the third core die 20c may be bonded to each other by copper-Cu hybrid bonding.

Accordingly, one module block MB including the first, second and third reconstruction dies RD1, RD2 and RD3 stacked in three stages between the first carrier substrate C1 and the third carrier substrate C3 may be formed.

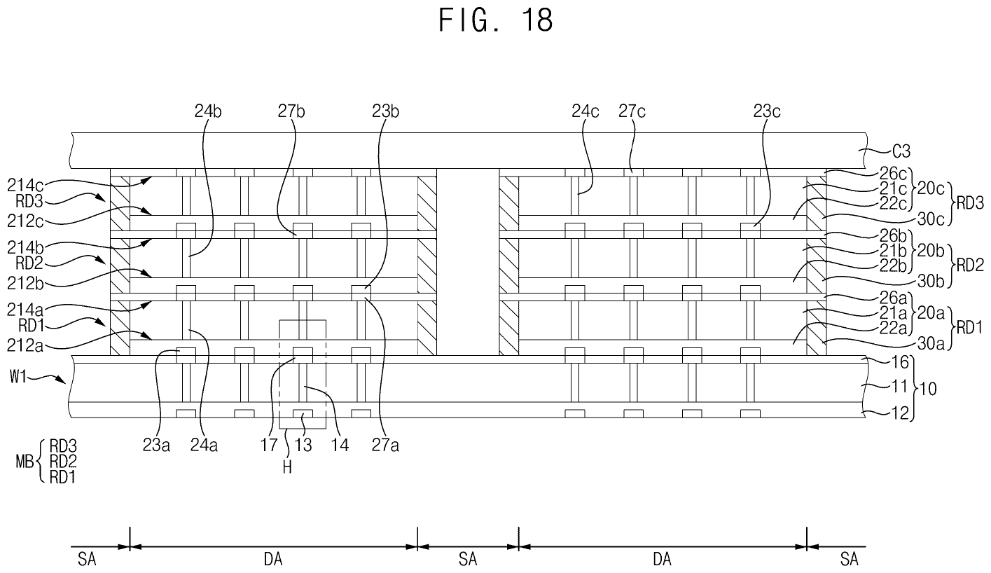

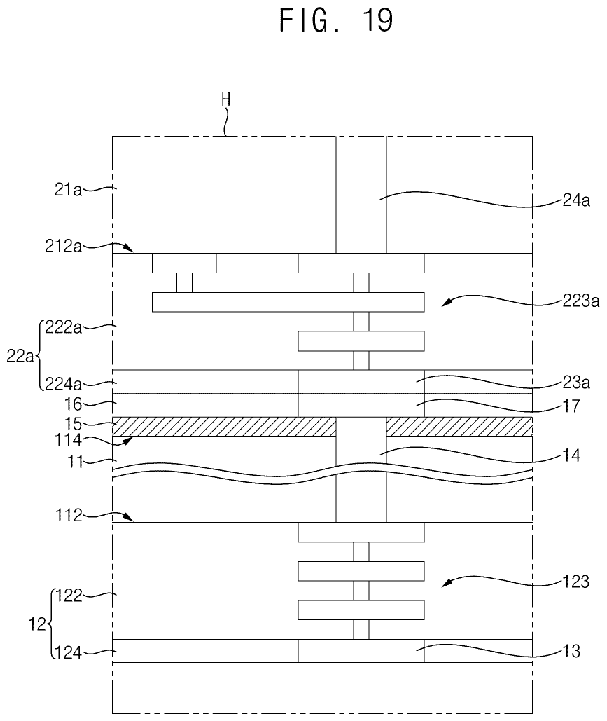

Referring to FIGS. 18 and 19, the module block MB may be attached on a first wafer W1 including buffer dies. For example, the module blocks MB on the third carrier substrate C3 may be attached on the first wafer W1 (e.g., a wafer-to-wafer hybrid bonding process). In some embodiments, the corresponding module blocks MB may be attached to the buffer dies of the first wafer W1 (e.g., a die-to-wafer hybrid bonding process). The module blocks MB may be spaced apart from each other on the first wafer W1.

As illustrated in FIG. 19, when the first reconstruction dies RD1 of the module block MB on the third carrier substrate C3 and the first wafer W1 are bonded to each other by wafer-to-wafer bonding, the first core die 20a of the first reconstruction die RD1 and the buffer die of the first wafer W1 may be hybrid-bonded to each other by a thermal compression process and an annealing process. That is, the first front insulating layer 22a on the front surface of the first core die 20a may be directly bonded to a backside insulating layer 16 on a backside surface of the first wafer W1c, and a second bonding pad 17c of the first wafer W1 and the first bonding pad 23a of the first core die 20a may be bonded to each other by copper-copper hybrid bonding (Cu—Cu Hybrid Bonding).

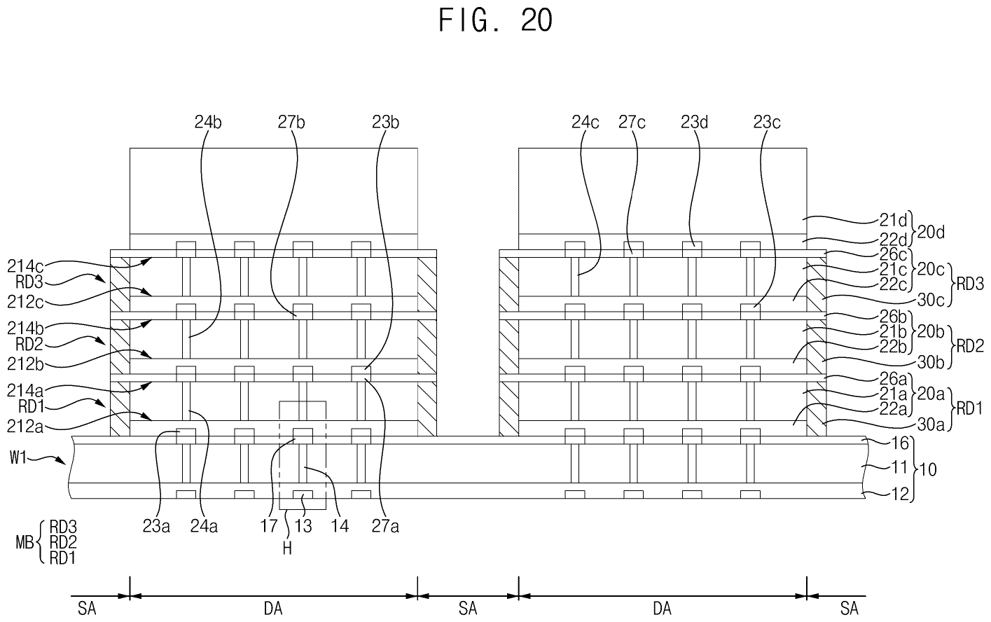

Referring to FIG. 20, top core dies 20d may be attached to the module blocks MB on the first wafer W1 (die-to-wafer hybrid bonding process). In some embodiments, after forming fourth reconstruction dies including top core dies 20d on a fourth carrier substrate, the fourth reconstruction dies on the fourth carrier substrate may be attached on the module blocks MB on the first wafer W1 (e.g., a wafer-to-wafer hybrid bonding process).

A second surface 214d of a substrate 21d of the top core die 20d may be stacked to face the first wafer W1. A thickness of the top core die 20d may be greater than a thickness of each of the intermediate core dies 20a, 20b, 20c. The thickness of the top core die 20d may be in a range of 100 μm to 300 μm. The thickness of each of the intermediate core dies 20a, 20b, 20c may be in a range of 20 μm to 50 μm.

When the top core die 20d and the module block MB are bonded to each other, the top core die 20d and the third core die 20c of the module block MB are bonded to each other by hybrid bonding by performing a thermal compression process and an annealing process. That is, a front insulating layer 22d on the front surface of the top core die 20d may be directly bonded to the backside insulating layer 26c on the backside surface of the third core die 20c, and the second bonding pad 27c of the third core die 20c and a first bonding pad 23d of the top core die 20d may be bonded to each other by Cu—Cu Hybrid Bonding.

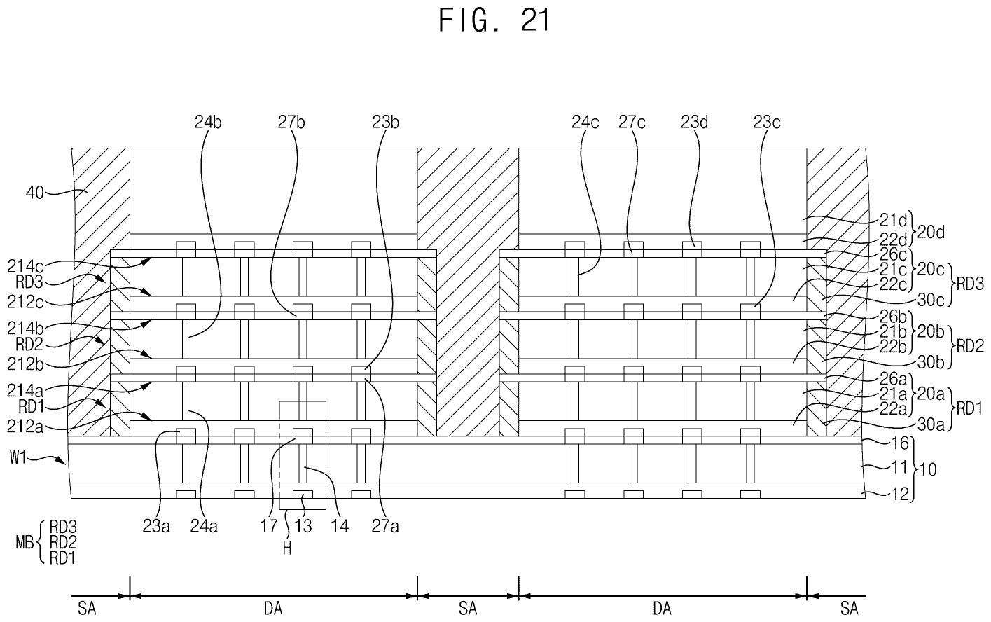

Referring to FIG. 21, a second gap filling portion 40 may be formed to cover or overlap side surfaces of the first to third reconstruction dies RD1, RD2 and RD3 of the module block MB and the top core dies 20d.

In example embodiments, the second gap filling portion 40 may be formed on the first wafer W1 to fill between the module blocks MB and between the top core dies 20d.

In particular, after a molding material is formed to cover or overlap the top core dies 20d on the module blocks MB on the first wafer W1, an upper portion of the molding material may be removed to form the second gap filling portion 40 that exposes upper surfaces of the top core dies 20d. The second gap filling portion 40 may directly contact the first gap filling portions 30a, 30b and 30c of the first, second and third reconstruction dies RD1, RD2 and RD3.

For example, the molding material may include a thermosetting resin. The molding material may include an epoxy mold compound (EMC). The molding material may include UV resin, polyurethane resin, silicone resin, silica filler, etc.

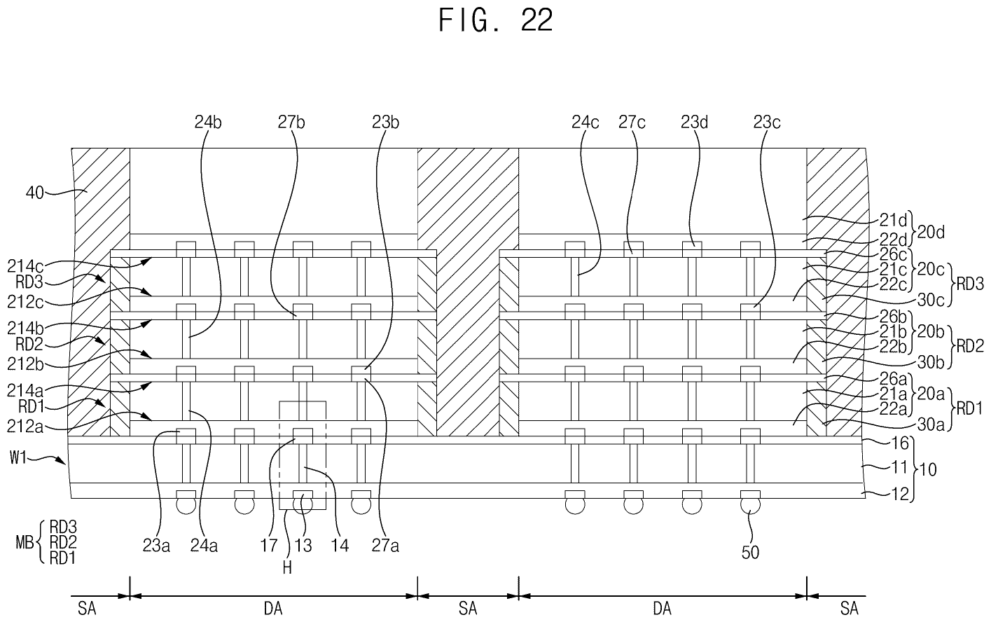

Referring to FIG. 22, conductive bumps 50 as conductive connection members may be formed on first bonding pads 13 of the first wafer W1.

For example, a seed layer may be formed on the first bonding pad 13 of the front insulating layer 12 of the first wafer W1, and a photoresist pattern having openings that expose portions of the seed layer may be formed on the seed layer on a front insulating layer 12. Then, the openings of the photoresist pattern may be filled up with a conductive material, the photoresist pattern may be removed and a reflow process may be performed to form solder bumps. For example, the conductive material may be formed on the seed layer by a plating process. In some embodiments, the conductive bump may include a pillar bump and a solder bump formed on the pillar bump.

Then, portions of the first wafer W1 and the second gap filling portion 40 may be cut along the scribe lane region SA to complete a semiconductor package 100 of FIG. 1.

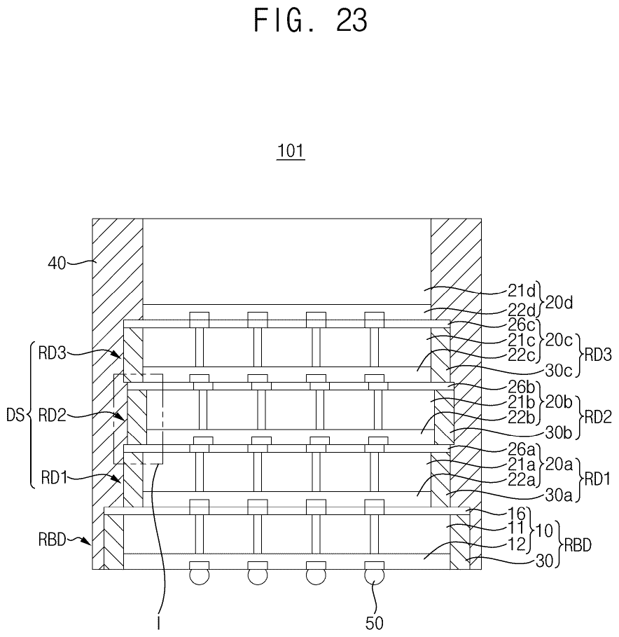

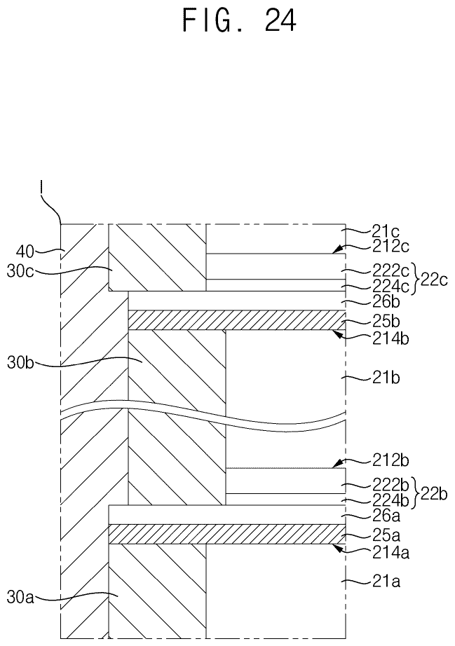

FIG. 23 is a cross-sectional view illustrating a semiconductor package in accordance with example embodiments. FIG. 24 is an enlarged cross-sectional view illustrating portion ‘I’ in FIG. 22. The semiconductor package is substantially the same as or similar to the semiconductor package described with reference to FIG. 1 except for configurations of a buffer die and a second gap filling portion. Thus, same reference numerals will be used to refer to the same or like elements and any further repetitive explanation concerning the above elements will be omitted.

Referring to FIGS. 23 and 24, a semiconductor package 101 may include a reconstruction buffer die RBD, a middle core die stack DS stacked on the reconstruction buffer die RBD, a top core die 20d, and a second gap filling portion 40. The intermediate core die stack DS may include first, second and third reconstruction dies RD1, RD2 and RD3 stacked in three stages.

In example embodiments, the reconstruction buffer die RBD may include a buffer die 10 and a first gap filling portion 30 that covers or overlaps a side surface of the buffer die 10. The first gap filling portion 30 may cover the side surfaces of a substrate 11 and a front insulating layer 12. A backside insulating layer 16 may cover or overlap an upper surface of the first gap filling portion 30.

A width of the reconstruction buffer die RBD may be greater than a width of the intermediate core die stack DS. The width of the middle core die stack DS may be greater than a width of the top core die 20d.

In example embodiments, the second gap filling portion 40 as a molding member may be provided to cover or overlap side surfaces of the reconstruction buffer die RBD, the intermediate core die stack DS, and the top core die 20d. The second gap filling portion 40 may directly contact a first gap filling portion 30 of the reconstruction buffer die RBD. The second gap filling portion 40 may cover or overlap a portion of the backside insulating layer 16 of the reconstruction buffer die RBD exposed by the intermediate core die stack DS.

As illustrated in FIG. 24, the second reconstruction die RD2 may be misaligned on the first reconstruction die RD1 so that the side surface of the first reconstruction die RD1 and the side surface of the second reconstruction die RD2 are positioned on different planes. The side surface of the first gap filling portion 30a of the first reconstruction die RD1 and the side surface of the first gap filling portion 30b of the second reconstruction die RD2 may be positioned on different planes.

The third reconstruction die RD3 may be misaligned on the second reconstruction die RD2, so that the side surface of the second reconstruction die RD2 and the side surface of the third reconstruction die RD3 may be positioned on different planes. The side surface of the first gap filling portion 30b of the second reconstruction die RD2 and the side surface of the first gap filling portion 30c of the third reconstruction die RD3 may be positioned on different planes.

Hereinafter, a method of manufacturing the semiconductor package of FIG. 23 will be described.

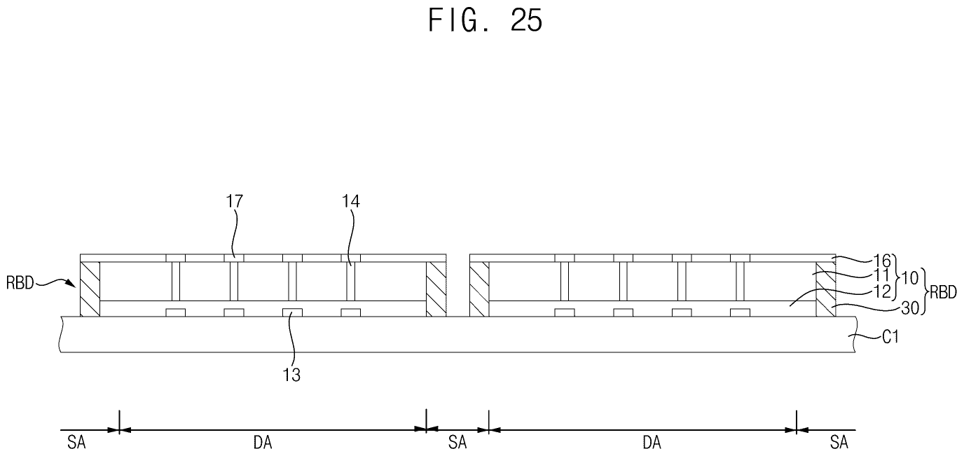

FIGS. 25 to 31 are views illustrating a method of manufacturing a semiconductor package in accordance with example embodiments.

Referring to FIG. 25, processes the same as or similar to the processes described with reference to FIGS. 4 to 12 may be performed to for reconstruction buffer dies RBD on a first carrier substrate C1.

The reconstruction buffer dies RBD may be arranged to be spaced apart from each other at a wafer level on the first carrier substrate C1. The reconstruction buffer dies RBD may be disposed on the first carrier substrate C1 such that a first surface 112 of a substrate 11 of the reconstruction buffer die RBD faces the first carrier substrate C1. Each of the reconstruction buffer dies RBD may include a buffer die 10 and a first gap filling portion 30 that covers or overlaps a side surface of the buffer die 10. The first gap filling portion 30 may cover or overlap side surfaces of the substrate 11 and a front insulating layer 12. A backside insulating layer 16 may cover or overlap a lower surface of the first gap filling portion 30.

As illustrated in FIG. 24, processes the same as or similar to the processes described with reference to FIGS. 4 to 12 may be performed to form first reconstruction dies RD1 on a second carrier substrate C2, and the first reconstruction dies RD1 on the second carrier substrate C2 may be attached to the reconstruction buffer dies RBD on the first carrier substrate C1 (e.g., a wafer-to-wafer hybrid bonding process).

When the first reconstruction dies RD1 on the second carrier substrate C2 and the reconstruction buffer dies RBD on the first carrier substrate C1 are bonded to each other by wafer-to-wafer bonding, a first core die 20a of the first reconstruction die RD1 and the buffer die 10 of the reconstruction buffer die RBD may be bonded to each other by hybrid bonding by performing a thermal compression process and an annealing process. That is, a front insulating layer 22a on a front surface of a first core die 20a may be directly bonded to the backside insulating layer 16 on a backside surface of the buffer die 10a, and the second bonding pad 17 of the buffer die 10 and a first bonding pads 23a of the first core die 20a may be bonded to each other by copper-Cu hybrid bonding.

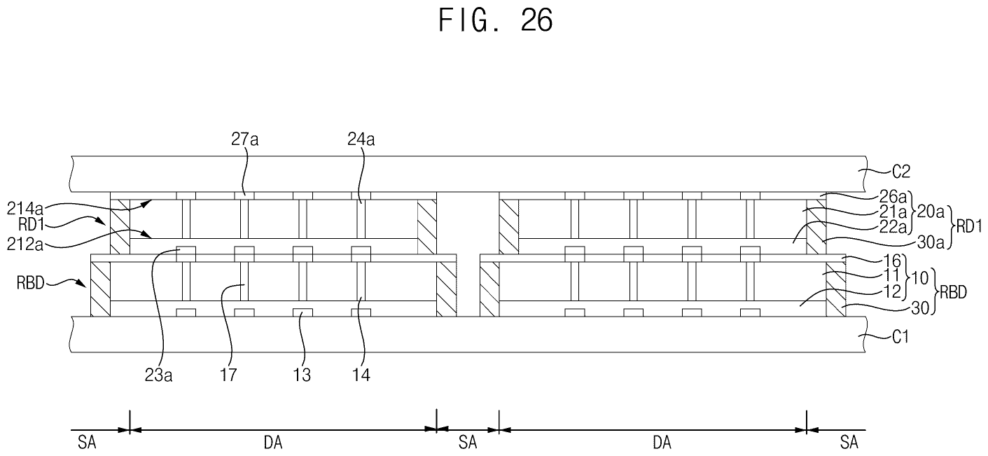

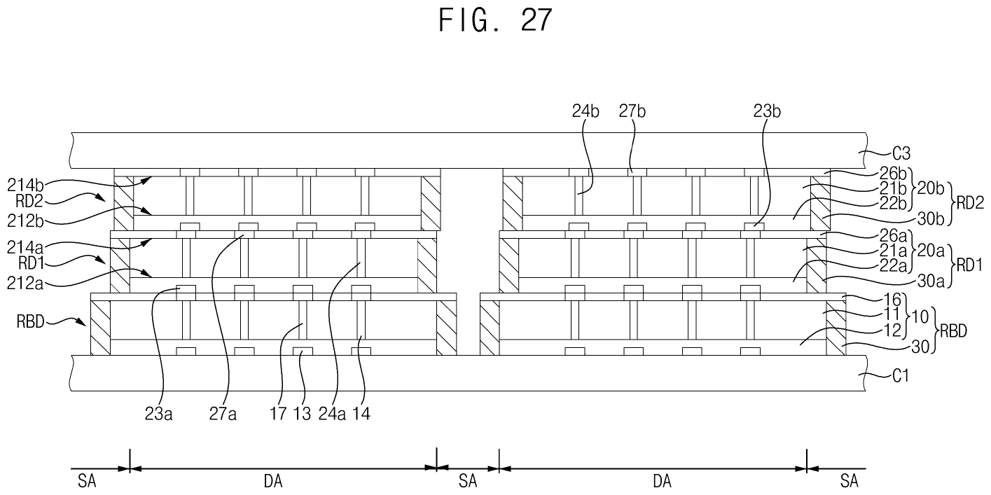

Referring to FIG. 27, processes the same as or similar to the processes described with reference to FIG. 26 may be performed to attach second reconstruction dies RD2 on the first reconstruction dies RD1 on the first carrier substrate C1.

Processes the same as or similar to the processes described with reference to FIGS. 4 to 12 may be performed to form the second reconstruction dies RD2 on a third carrier substrate C3, and then, the second reconstruction dies RD2 on the third carrier substrate C3 may be attached on the first reconstruction dies RD1 on the first carrier substrate C1 (e.g., a wafer-to-wafer hybrid bonding process).

When the second reconstruction dies RD2 on the third carrier substrate C3 and the first reconstruction dies RD1 on the first carrier substrate C1 are bonded to each other by wafer-to-wafer bonding, a second core die 20b of the second reconstruction die RD2 and the first core die 20a of the first reconstruction die RD1 may be bonded to each other by hybrid bonding by performing a thermal compression process and an annealing process. That is, a front insulating layer 22b on a front surface of the second core die 20b may be directly bonded to a backside insulating layer 26a on a backside surface of the first core die 20a, and a second bonding pad 27a of the first core die 20a and a first bonding pad 23b of the second core die 20b may be bonded to each other by copper-Cu hybrid bonding.

At this time, since the second reconstruction dies RD2 and the first reconstruction dies RD1 are bonded to each other by wafer-to-wafer bonding, the second reconstruction die RD2 may be misaligned on the corresponding first reconstruction die RD1, so that a side surface of the first reconstruction die RD1 and a side surface of the second reconstruction die RD2 may be positioned on different planes. A side surface of a first gap fill portion 30a of the first reconstruction die RD1 and a side surface of a first gap filling portion 30b of the second reconstruction die RD2 may be positioned on different planes.

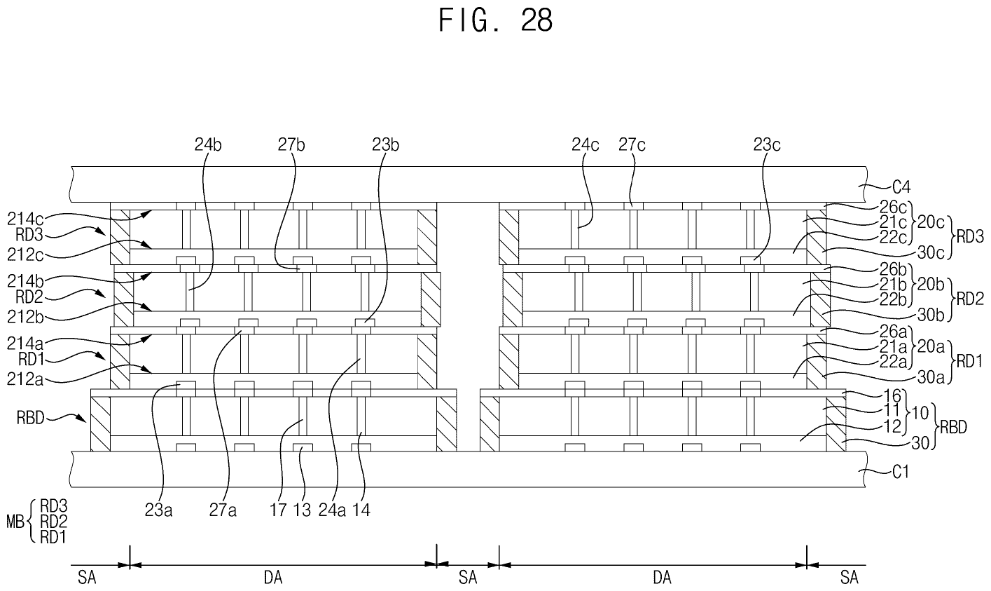

Referring to FIG. 28, processes the same as or similar to the processes described with reference to FIG. 27 may be performed to attach third reconstruction dies RD3 on the second reconstruction dies RD2 on the first carrier substrate C1.

Processes the same as or similar to the processes described with reference to FIGS. 4 to 12 may be performed to form the third reconstruction dies RD3 on a fourth carrier substrate C4, and then, the third reconstruction dies RD3 on the fourth carrier substrate C4 may be attached on the second reconstruction dies RD2 on the first carrier substrate C1 (e.g., a wafer-to-wafer hybrid bonding process).

When the third reconstruction dies RD3 on the fourth carrier substrate C4 and the second reconstruction dies RD2 on the first carrier substrate C1 are bonded to each other by wafer-to-wafer bonding, a third core die 20c of the third reconstruction die RD3 and the second core die 20b of the second reconstruction die RD3 may be bonded to each other by hybrid bonding by performing a thermal compression process and an annealing process. That is, a front insulating layer 22c on a front surface of the third core die 20c may be directly bonded to a backside insulating layer 26b on a backside surface of the second core die 20b, and a second bonding pad 27b of the second core die 20b and a first bonding pad 23c of the third core die 20c may be bonded to each other by copper-Cu hybrid bonding.

Thus, a module block MB including the first, second and third reconstruction dies RD1, RD2 and RD3 stacked in three stages on the reconstruction buffer die RBD between the first carrier substrate C1 and the fourth carrier substrate C4 may be formed.

At this time, since the third reconstruction dies RD3 and the second reconstruction dies RD2 are bonded to each other by wafer-to-wafer bonding, the third reconstruction die RD3 may be misaligned on the corresponding second reconstruction die RD3, so that a side surface of the second reconstruction die RD2 and a side surface of the third reconstruction die RD3 may be positioned on different planes. A side surface of a first gap fill portion 30b of the second reconstruction die RD3 and a side surface of a first gap filling portion 30c of the third reconstruction die RD3 may be positioned on different planes.

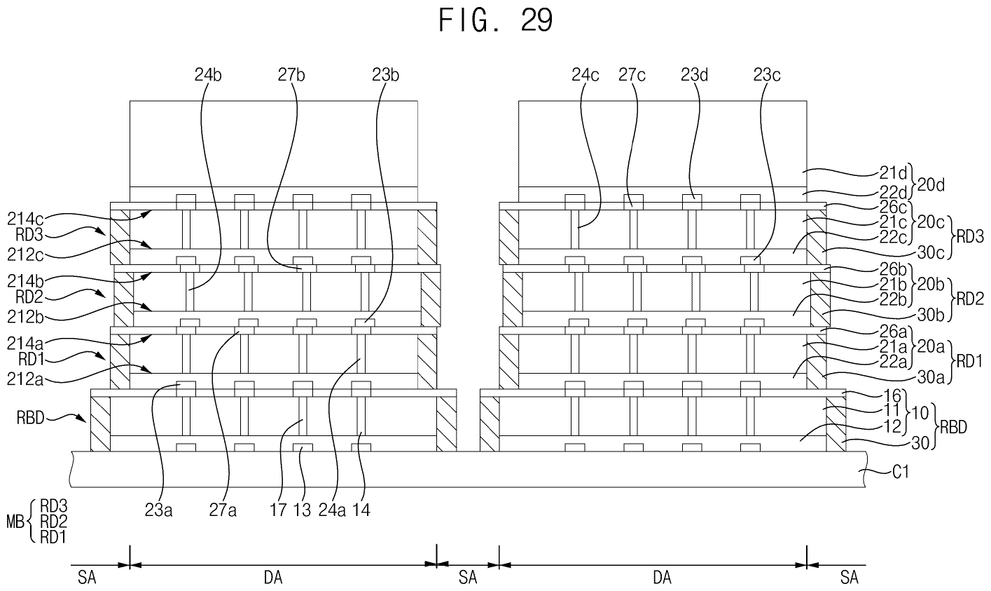

Referring to FIG. 29, top core dies 20d may be attached to the module blocks MB on the reconstruction buffer die RBD (e.g., a die-to-wafer hybrid bonding process). In some embodiments, after forming fourth reconstruction dies including top core dies 20d on a fifth carrier substrate, the fourth reconstruction dies on the fifth carrier substrate may be attached on the module blocks MB on the reconstruction buffer die RBD (e.g., a wafer-to-wafer hybrid bonding process).

A second surface 214d of a substrate 21d of the top core die 20d may be stacked to face the first carrier substrate C1. A thickness of the top core die 20d may be greater than a thickness of each of the intermediate core dies 20a, 20b, 20c. The thickness of the top core die 20d may be in a range of 100 μm to 300 μm. The thickness of each of the intermediate core dies 20a, 20b, 20c may be in a range of 20 μm to 50 μm.

When the top core die 20d and the module block MB are bonded to each other, the top core die 20d and the third core die 20c of the module block MB are bonded to each other by hybrid bonding by performing a thermal compression process and an annealing process. That is, a front insulating layer 22d on the front surface of the top core die 20d may be directly bonded to the backside insulating layer 26c on the backside surface of the third core die 20c, and the second bonding pad 27c of the third core die 20c and a first bonding pad 23d of the top core die 20d may be bonded to each other by Cu—Cu Hybrid Bonding.

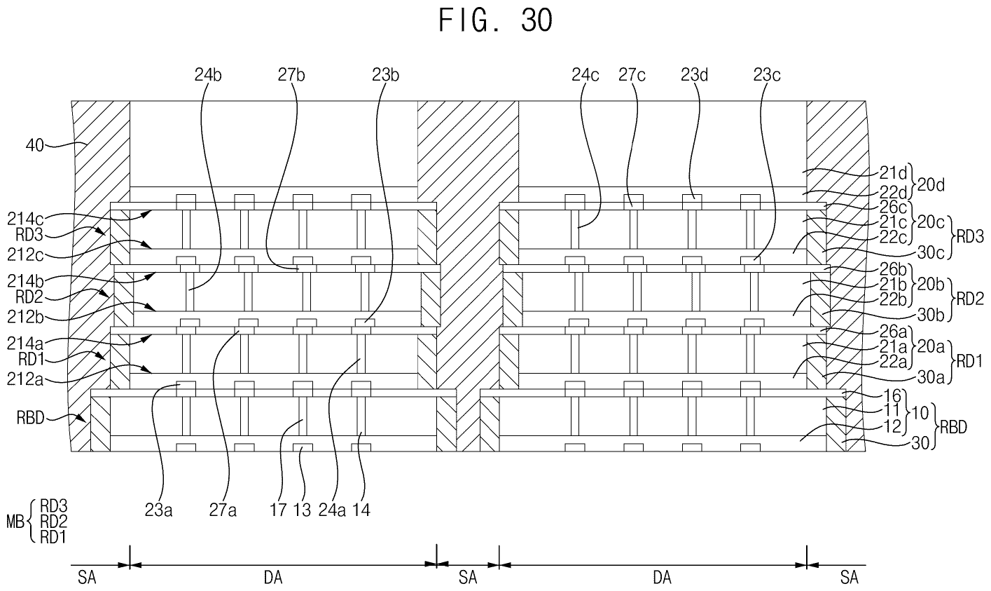

Referring to FIG. 30, a second gap filling portion 40 may be formed to cover or overlap side surfaces of the reconstruction buffer die RBD, the first to third reconstruction dies RD1, RD2 and RD3 of the module block MB and the top core die 20d.

In example embodiments, the second gap filling portion 40 may be formed on the first carrier substrate C1 to fill or be between the reconstruction buffer dies RBD, the module blocks MB and between the top core dies 20d.

In particular, after a molding material is formed to cover or overlap the top core dies 20d on the module blocks MB on the first carrier substrate C1, an upper portion of the molding material may be removed to form the second gap filling portion 40 that exposes upper surfaces of the top core dies 20d. The second gap filling portion 40 may directly contact the first gap filling portion 30 of the reconstruction buffer die RBD and the first gap filling portions 30a, 30b and 30c of the first, second and third reconstruction dies RD1, RD2 and RD3.

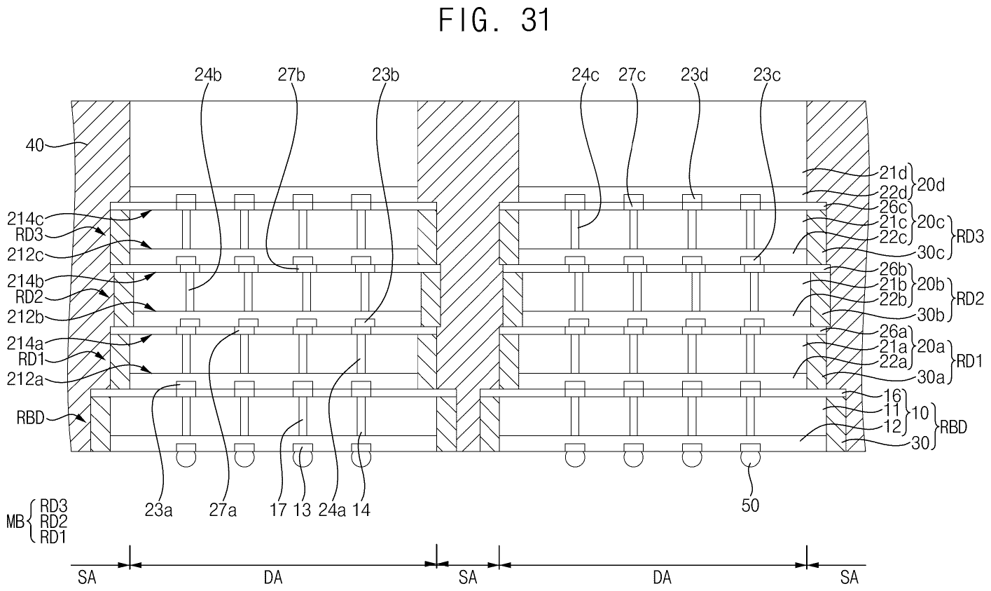

Referring to FIG. 31, conductive bumps 50 as conductive connection members may be formed on first bonding pads 13 of the buffer die 10 of the reconstruction buffer die RBD.

Then, a portion of the second gap filling portion 40 may be cut along a scribe lane region SA to complete a semiconductor package 101 of FIG. 23.

The semiconductor package may include semiconductor devices such as logic devices or memory devices. The semiconductor package may include logic devices such as central processing units (CPUs), main processing units (MPUs), or application processors (APs), or the like, and volatile memory devices such as DRAM devices, HBM devices, or non-volatile memory devices such as flash memory devices, PRAM devices, MRAM devices, ReRAM devices, or the like.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages of the present disclosure. Accordingly, all such modifications are intended to be included within the scope of example embodiments as defined in the claims.

What is claimed is:

1. A semiconductor package, comprising:
a buffer die;
an intermediate core die stack on the buffer die, wherein the intermediate core die stack comprises a plurality of intermediate core dies and a plurality of first gap filling portions that respectively overlap side surfaces of the plurality of intermediate core dies in a first direction;
a top core die on the intermediate core die stack; and
a second gap filling portion that overlaps side surfaces of the intermediate core die stack in the first direction and side surfaces of the top core die in the first direction.

2. The semiconductor package of claim 1, wherein each of the intermediate core dies comprises:
a substrate;
a front insulating layer that is on a front surface of the substrate;
a first bonding pad in the front insulating layer; and
a backside insulating layer that is on a backside surface of the substrate and comprises a second bonding pad.

3. The semiconductor package of claim 2, wherein:
a first intermediate core die among the plurality of intermediate core dies is on a second intermediate core die among the plurality of intermediate core dies,
the backside insulating layer of the first intermediate core die and the front insulating layer of the second intermediate core die are directly bonded to each other, and
the second bonding pad of the first intermediate core die and the first bonding pad of the second intermediate core die are directly bonded to each other.

4. The semiconductor package of claim 2, wherein each of the intermediate core dies further comprises a through electrode that extends into the substrate and is electrically connected to the first bonding pad and the second bonding pad.

5. The semiconductor package of claim 2, wherein the plurality of first gap filling portions overlap side surfaces of the substrate and side surfaces of the front insulating layer in the first direction.

6. The semiconductor package of claim 5, wherein the backside insulating layer overlaps an upper surface of the plurality of first gap filling portions in a second direction that intersects the first direction.

7. The semiconductor package of claim 1, wherein a first one of the plurality of first gap filling portions comprises an inorganic dielectric material or an organic dielectric material.

8. The semiconductor package of claim 1, wherein the second gap filing portion comprises a thermosetting resin.

9. The semiconductor package of claim 1, wherein the second gap filling portion directly contacts the plurality of the first gap filling portions.

10. The semiconductor package of claim 1, wherein the second gap filling portion overlaps a side surface of the buffer die in the first direction.

11. A semiconductor package, comprising:
a buffer die;
a plurality of reconstruction dies that are on the buffer die, wherein each of the plurality of reconstruction dies comprises an intermediate core die and a first gap filling portion that overlaps a side surface of the intermediate core die in a first direction;
a top core die on the plurality of reconstruction dies; and
a second gap filling portion that overlaps side surfaces of the plurality of reconstruction dies in the first direction and side surfaces of the top core die in the first direction,
wherein each of the plurality of reconstruction dies comprises:
a substrate,
a front insulating layer on a front surface of the substrate, a first bonding pad in the front insulating layer,
a backside insulating layer on a backside surface of the substrate, and
a second bonding pad in the backside insulating layer, and
wherein the second gap filling portion directly contacts the first gap filling portion of each of the plurality of reconstruction dies.

12. The semiconductor package of claim 11, wherein the backside surface of the substrate of a first intermediate core die of a first reconstruction die of the plurality of reconstruction dies and the front surface of the substrate of a second intermediate core die of a second reconstruction die of the plurality of reconstruction dies face each other, and wherein the second reconstruction die is on the first reconstruction die.

13. The semiconductor package of claim 12, wherein:
the backside insulating layer of the first intermediate core die and the front insulating layer of the second intermediate core die are directly bonded to each other, and
the second bonding pad of the first intermediate core die and the first bonding pad of the second intermediate core die are directly bonded to each other.

14. The semiconductor package of claim 11, wherein the first gap filling portion comprises an inorganic dielectric or an organic dielectric.

15. The semiconductor package of claim 11, wherein the second gap filing portion comprises a thermosetting resin.

16. The semiconductor package of claim 11, wherein the first gap filling portion overlaps side surfaces of the substrate in the first direction and side surfaces the front insulating layer in the first direction.

17. The semiconductor package of claim 16, wherein the backside insulating layer overlaps an upper surface of the first gap filling portion in a second direction that intersects the first direction.

18. The semiconductor package of claim 11, wherein the second gap filling portion overlaps a side surface of the buffer die in the first direction.

19. The semiconductor package of claim 11, wherein the first bonding pad and the second bonding pad comprise copper.

20. A semiconductor package, comprising:
a buffer die;
an intermediate core die stack on the buffer die;
a top core die on the intermediate core die stack; and
a molding member that at least partially overlaps side surfaces of the intermediate core die stack and the top core die,
wherein the intermediate core die stack comprises:
a plurality of intermediate core dies that are stacked on one another; and
a plurality of gap fill portions that at least partially overlap respective side surfaces of the plurality of intermediate core dies, and
wherein the molding member directly contacts the plurality of gap fill portions.
